(19) United States
(12) Patent Application Publication
(10) Pub. No.: US 2024/0426916 A1
(43) Pub. Date: Dec. 26, 2024

(54) INFORMATION PROCESSING APPARATUS, INFORMATION PROCESSING METHOD, INFORMATION PROCESSING SYSTEM, AND NON-TRANSITORY COMPUTER READABLE MEDIUM

(71) Applicants: KABUSHIKI KAISHA TOSHIBA, Tokyo (JP); TOSHIBA ENERGY SYSTEMS & SOLUTIONS CORPORATION, Kawasaki-shi (JP)

(72) Inventors: Tomoshi OTSUKI, Kawasaki (JP); Chihiro KASAI, Kawasaki (JP); Sunao YOTSUTSUJI, Kawasaki (JP); Ryusei SHINGAKI, Tokyo (JP)

(73) Assignees: KABUSHIKI KAISHA TOSHIBA, Tokyo (JP); TOSHIBA ENERGY SYSTEMS & SOLUTIONS CORPORATION, Kawasaki-shi (JP)

(21) Appl. No.: 18/599,889

(22) Filed: Mar. 8, 2024

(30) Foreign Application Priority Data
Jun. 20, 2023 (JP) 2023-101210

(51) Int. Cl. G01R 31/36

(52) U.S. Cl. CPC G01R 31/36

(57) ABSTRACT

According to one embodiment, an information processing apparatus, comprises a processing circuitry configured to estimate, based on histories of charge and discharge of storage batteries of one or more consumers in a first period, remaining capacities of the storage batteries in a second period different from the first period, and calculate a power adjustable capacity that is a total of rechargeable capacities or dischargeable capacities of the storage batteries of the one or more consumers in the second period, based on estimates of the remaining capacities of the storage batteries.

### CROSS REFERENCE TO RELATED APPLICATIONS

This application is based upon and claims the benefit of priority from the prior Japanese Patent Application No. 2023-101210, filed on Jun. 20, 2023, the entire contents of which are incorporated herein by reference.

### FIELD

Embodiments of the present invention relate to an information processing apparatus, an information processing method, an information processing system, and a non-transitory computer readable medium.

### BACKGROUND

For stabilizing power systems, it has been required to adjust electric power supply and demand, and balance supply and demand. Meanwhile, household electric vehicles (EVs) and storage batteries have large underutilized capacities (charge capacities stored in storage batteries and left unused). By collecting them much, a certain scale of resources can be made up. Consequently, it is conceivable that through collection of a large number of household EVs and storage batteries, power adjustment capability is securely achieved, and a total demand of consumers are accommodated within the upper and lower limit range of the power adjustment capability, thus balancing the power supply and demand.

However, since household consumers' demands greatly vary, it is sometimes difficult to adjust supply and demand. Charge and discharge control, such as an economic priority mode, and water heater scheduling, for household EVs and storage batteries are often set on the household side. The set control details cannot be identified from the outside. Accordingly, the household side is not always responsive to a charge and discharge request. The households have time slots in which EVs are absent. Accordingly, the uncertainty of response to a charge and discharge request is high. Actual charge and discharge capacities of consumers are often determined by the contracted power (often smaller than the output capability of the storage batteries), or by the restriction on the reverse power flow (for example, the reverse power flow from storage batteries is sometimes prohibited), instead of the output characteristics of the storage batteries.

Because of the uncertainty as described above, it is difficult to preliminarily calculate the power adjustable capacity (DR capability) of each customer in a case of issuance of a demand response (DR) request that is a request for adjusting supply and demand. Meanwhile, in a balancing market, bidding capacities are required to be determined by the day before. For economic DR, it is desirable to preliminarily know the power adjustable capacities. Consequently, it is required to preliminarily calculate the power adjustable capacities at high accuracy under an uncertain condition.

### BRIEF DESCRIPTION OF THE DRAWINGS

FIG. 1 is a diagram showing an overview of an entire system configuration according to the present embodiment;

FIG. 2 is a diagram showing item categories of a balancing market;

FIG. 3 is a diagram showing requirements for a tertiary adjustment capability [1], and a tertiary adjustment capability [2] in detail;

FIG. 4 is a diagram showing the flow of a control instruction and the positioning of a resource aggregator (RA) in VPP demonstration;

FIG. 5 is a diagram showing the flow of actual value calculation in the VPP demonstration;

FIG. 6 is a diagram illustrating a preliminary review method for the tertiary adjustment capability [2];

FIG. 7 is a diagram illustrating the preliminary review method for the tertiary adjustment capability [2];

FIG. 8 is a diagram for illustrating an example of success determination in the tertiary adjustment capability [1];

FIG. 9 is a block diagram showing a configuration of a DR capability estimation apparatus and consumers according to the present embodiment;

FIG. 10 is a block diagram showing a simplified configuration where some components are omitted from the configuration shown in FIG. 9;

FIG. 11 is a diagram showing examples of SoC time-series estimates and disconnected time-series estimates;

FIG. 12 is a diagram showing an example of demand time-series estimates;

FIG. 13 is a diagram showing an example of DR content information in a case of a balancing market;

FIG. 14 is a diagram showing an example of DR content information in a case of an economic DR;

FIG. 15 is a diagram showing an example of storage battery specification information;

FIG. 16A is a diagram showing an example of a calculation result of rechargeable and dischargeable capacities without consideration of original storage battery control, and FIG. 16B is a diagram showing an example of a calculation result of rechargeable and dischargeable capacities in consideration of storage battery control;

FIG. 17 is a supplementary explanation diagram of calculation of rechargeable and dischargeable capacities in consideration of original storage battery control;

FIG. 18 is a diagram showing an example of parameter information;

FIG. 19 is a diagram showing an example of a DR capability DB;

FIG. 20 is a flowchart of processes of the simplified configuration in FIG. 10;

FIG. 21 is a diagram showing DR capability information in a case of increase DR;

FIG. 22A is a diagram showing an example of the DR content information, FIG. 22B is a diagram showing an example of values of coefficients, and FIG. 22C is a diagram showing an example of calculation results of DR capabilities;

FIG. 23 is a diagram showing a calculation example of DR capabilities in Embodiment 4;

FIG. 24 is a diagram showing an example of a flowchart in consideration of an estimation deviation risk;

FIG. 25 is a diagram showing a specific example of operation in Embodiment 5;

FIG. 26 shows an example of an output screen of a display; and FIG. 27 is a diagram showing a hardware configuration of the DR capability estimation apparatus that is an information processing apparatus in the present embodiment.

### DETAILED DESCRIPTION

According to one embodiment, an information processing apparatus, comprises a processing circuitry configured to estimate, based on histories of charge and discharge of storage batteries of one or more consumers in a first period, remaining capacities of the storage batteries in a second period different from the first period, and calculate a power adjustable capacity that is a total of rechargeable capacities or dischargeable capacities of the storage batteries of the one or more consumers in the second period, based on estimates of the remaining capacities of the storage batteries.

Hereinafter, referring to the drawings, the present embodiments are described.

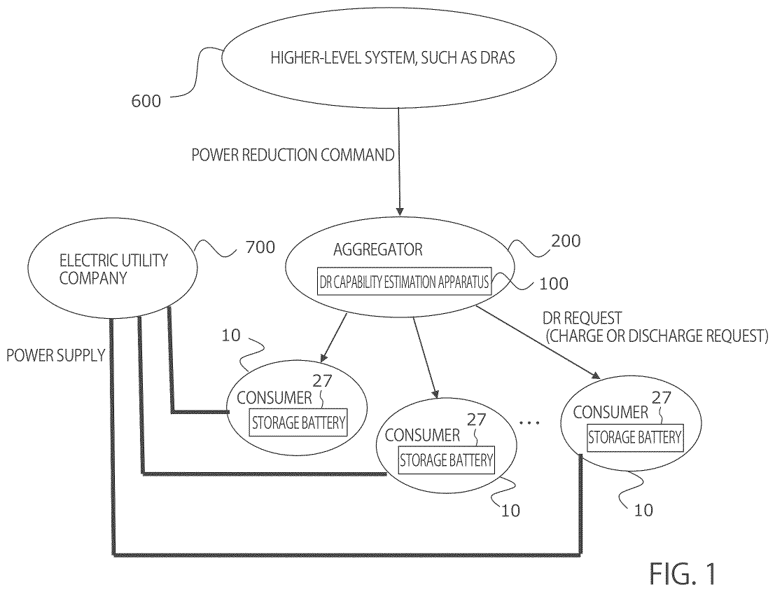

FIG. 1 is a diagram showing an overview of an entire system configuration according to the present embodiment.

The present embodiment mainly includes: consumers 10 that each uses power, and holds a storage battery 27; an electric utility company 700 that supplies power to each consumer 10; a higher-level system 600, such as a demand response application server (DRAS), which issues a control command for power supply and demand (a power reduction command in the shown example); and an aggregator 200 that mediates the consumers 10. The illustrated example assumes “reduction DR” that is a request for reducing the demand (power consumption) of the entire consumers, a reduction command as a control command is issued. However, in a case of “increase DR” that is a request for increasing demand (power consumption) of the entire consumers, a power consumption command is issued. In operation of the power system, the aggregator 200 mediates the electric utility company 700, such as a power supplier that generates or distributes power, and the consumers 10 that use power, and intend to reduce power. The aggregator 200 promises power reduction for the electric utility company 700, and makes a power reduction plan (e.g., a charge and discharge plan of the storage batteries 27) for the subordinate consumers 10, and requests the consumers 10 to charge or discharge power according to the plan. The request is called a demand response (DR) request. Accordingly, the aggregator 200 intends to achieve the object of power reduction in the entire consumers. Accordingly, the aggregator 200 includes a DR capability estimation apparatus 100 that estimates the power adjustable capacity (DR capability) of the entire consumers at high accuracy.

Households (low-voltage consumers) are mainly assumed as the consumers 10. However, the consumers 10 may be high-voltage consumers or extra-high voltage consumers, such as of office buildings, commercial buildings, public facilities, and factories. The electric utility company 700 and the higher-level system 600 may be an integrated entity. The electric utility company 700 may be a business operator (Utility) that integrally operates power generation to power distribution, or at least one business operator among a power transmission and distribution business operator, a retail business operator, and a power generation business operator.

The aggregator 200 issues a DR request (request for charge or discharge) to the consumer 10 according to a reduction command from the higher-level system 600. The aggregator 200 creates a charge and discharge plan (DR plan) for the storage batteries 27 held by the consumers 10, based on the reduction command from the higher-level system 600 and on information on the consumers 10 (consumer information), using the DR capability estimation apparatus 100 according to the present embodiment. The aggregator 200 issues a DR request (charge or discharge request) that is a control command for the storage batteries 27 to the subordinate consumers 10, based on the DR plan. Thus, the aggregator 200 achieves the object of power reduction in the entire consumers. The storage battery 27 of the consumer 10 controls charge and discharge in response to the charge or discharge request issued by the aggregator 200. The discharged power is sometimes used in the household premises of the consumers, and is sometimes used for power supply to a buyer in a case where the power is sold in a wholesale electricity exchange market.

The aggregator 200 may be included in at least one of the higher-level system 600 and the electric utility company 700. The aggregator 200 may have a structure with two tiers or more, and may have a structure where instead of the higher-level system 600, a parent aggregator commands a child aggregator, and the DR capability estimation apparatus 100 of the child aggregator mediates the patent aggregator and the consumers 10. The aggregator 200 may have a function of submitting a bid to a balancing market system that performs processes of an after-mentioned balancing market, or an electricity exchange market system that performs processes of an electricity exchange market (also called a wholesale electricity exchange market).

Hereinafter, an overview of the present embodiment is described assuming balancing market practices that started FY 2021.

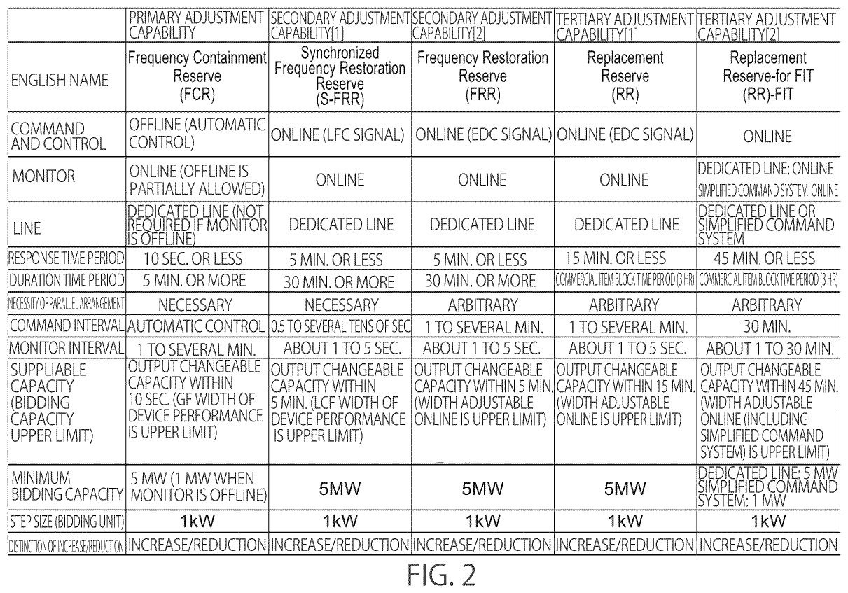

FIG. 2 shows item categories of a balancing market. FIG. 2 is based on a material excerpted from the Material 2 of the 13-th Balancing Market Discussion Subcommittee. The balancing market that started FY 2021 provides five types of commercial items depending on differences in response time periods etc. The response time period is a time period from issuance of a reduction command (also called a reduction request) from the higher-level system 600 to a response to the reduction command. The five types of commercial items include a primary adjustment capability, a secondary adjustment capability [1], a secondary adjustment capability [2], a tertiary adjustment capability [1], and a tertiary adjustment capability [2]. In a case of an aggregation that bundles the consumers (households) via the network, a communication delay of at least about one minute is assumed. Accordingly, two types that are the tertiary adjustment capability [1], and the tertiary adjustment capability [2] are assumed as main targets.

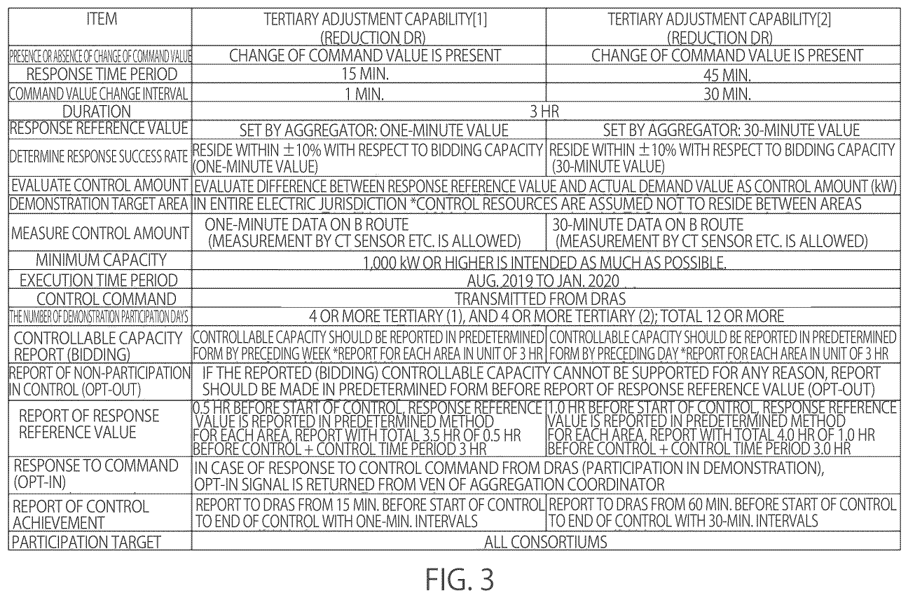

FIG. 3 shows requirements for the tertiary adjustment capability [1], and the tertiary adjustment capability [2] in detail.

FIG. 3 is based on a material excerpted from FY 2020 VPP business common demonstration specifications.

For example, as shown in FIG. 3 or FIG. 2 described above, the tertiary adjustment capability [2] has a response time period within 45 minutes. The duration time period (duration) is three hours that are a commercial item block time period. The command interval (command value change interval) is 30 minutes.

Here, the commercial item block time period is any of the followings.
0:00 to 3:00
3:00 to 6:00
6:00 to 9:00
9:00 to 12:00
12:00 to 15:00
15:00 to 18:00
18:00 to 21:00
21:00 to 24:00

For every commercial item block time period, the duration time period is three hours. The command interval (command value change interval) is thus 30 minutes. Accordingly, for example, in a case of commercial item block time period from 15:00 to 18:00, for each of 30-minute bands, i.e.,
15:00 to 15:30
15:30 to 16:00
16:00 to 16:30
16:30 to 17:00
17:00 to 17:30
17:30 to 18:00
   the command value (reduction command etc.) is determined.

Furthermore, the response time period is 45 minutes or less. Accordingly, for example, the reduction command value for a period from 15:00 to 15:30 is determined by 14:15. Note that if the aggregator receives no reduction command from the higher-level system 600 by 45 minutes earlier, the command value is assumed as 0 −(there is no reduction command).

The command value is determined in accordance with the bidding unit price or the contracted capacity. Accordingly, it is conceivable that the reduction command value may be highly possibly a value corresponding to “ΔkW contracted capacity” (described later) that is the maximum value. It is assumed that the bidding unit price is preliminarily determined by a freely selected method.

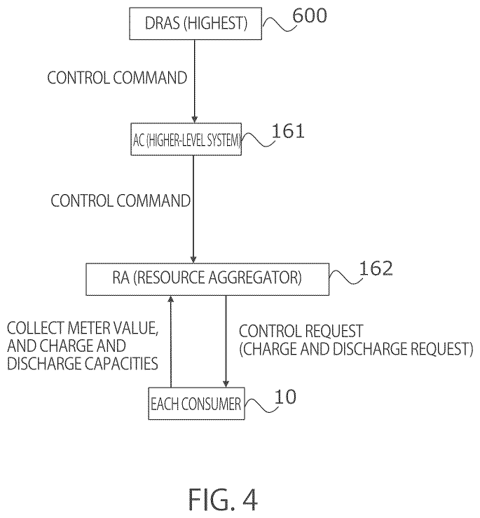

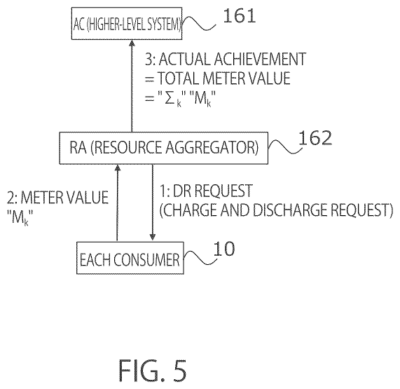

Referring to FIGS. 4 and 5, an example of a typical aggregation performed in a virtual power plant (VPP) demonstration experiment (https://sii.or.jp/vpp02/) and the like is described.

FIG. 4 is a diagram showing the flow of a control instruction and the positioning of a resource aggregator (RA) in VPP demonstration.

FIG. 5 is a diagram showing the flow of actual value calculation in the VPP demonstration.

In FIG. 4, for example, 15 minutes before DR start, a DR command (power reduction command etc.) that is a control command is notified to a resource aggregator (RA) 162 from the highest DRAS 600 held by an electric power business operator, via a higher-level aggregation coordinator (AC) 161. The combination of the AC 161 and the RA 162 corresponds to the aggregator 200. The control command includes, for example, a command for 10 kW reduction between 18:00 and 21:00. The RA 162 collects a measurement (sometimes called a meter value) of an electricity meter, and information on the charge and discharge capacities etc. of the storage batteries 27, from each consumer 10 as needed. Upon notification of the DR command (control command), the RA 162 performs estimation of demand of each subordinate consumer (demand estimation), based on the collected information, for example, two minutes before DR start, and performs DR optimizing process. The DR optimizing process determines the details of charge and discharge to be requested from each consumer, and generates a DR command (a charge command or a discharge command). The RA 162 notifies the calculated DR command, as a control request, to each consumer, for example, one minute before DR start. The DR optimizing process, and the notification of the control request to each consumer are performed, for example, every five minutes. As shown in FIG. 5, the meter values of the subordinate consumers 10 of RA 162 after completion of the DR execution is obtained, and DR achievement (DR success or failure) is determined based on the total value of the obtained meter values. Specifically, the DR achievement is determined based on how close to a DR target value the total value is. Consequently, the RA 162 is required to appropriately control the meter values of the electricity meters of the subordinate consumers by issuing DR requests (charge and discharge requests) to the respective consumers so as to make the total of the meter values of the electricity meters of the consumers close to the target value as much as possible.

Next, based on FY 2020 VPP business common demonstration specifications (https://sii.or.jp/vpp02/uploads/R2VPPkyoutujishousiyou.pdf), the currently assumed success condition of the tertiary adjustment capability is described.

As shown in FIG. 3 described above, the VPP demonstration business specifications defines success determination conditions for the tertiary adjustment capability [1] and the tertiary adjustment capability [2] such that the achievement demand capacity can be within +10% with respect to the bidding capacity (corresponding to the ΔkW contracted capacity of the balancing market). The evaluation unit is defined as one minute for the tertiary adjustment capability [1], and 30 minutes for the tertiary adjustment capability [2].

On the other hand, according to the Balancing Market Discussion Subcommittee, a preliminary review for the tertiary adjustment capability [2] has a requirement that the power reduction amount (power adjustment amount) at every five minutes is accommodated in a range of +10% of the contracted capacity with respect to the control instruction amount (e.g., reduction instruction amount) of an instruction by the control instruction from the higher-level system.

In the cases of the tertiary adjustment capability [1] and the tertiary adjustment capability [2] in the balancing market, a bid for an increasable/reducible electric energy is required to be made by the Specifically, in the case of the tertiary adjustment day before. capability [1], a bid is required to be made between 14:00 on Monday in the preceding week and 14:00 on Tuesday in the preceding week. In the case of the tertiary adjustment capability [2], a bid is required to be made between 12:00 and 14:00 the day before. Subsequently, between 14:00 and 15:00, a contract process is performed. If a contract is resultantly concluded, a ΔkW contracted capacity is calculated, and the ΔkW contracted capacity serves as the maximum value of the command value. Consequently, if the bidding capacity is too large, the risk of failure in increase/reduction DR increases accordingly. If it is too small, an appropriate incentive (determined by bidding capacity x bidding unit price) cannot be achieved. Accordingly, it is important to highly accurately estimate the bidding capacity by the day before.

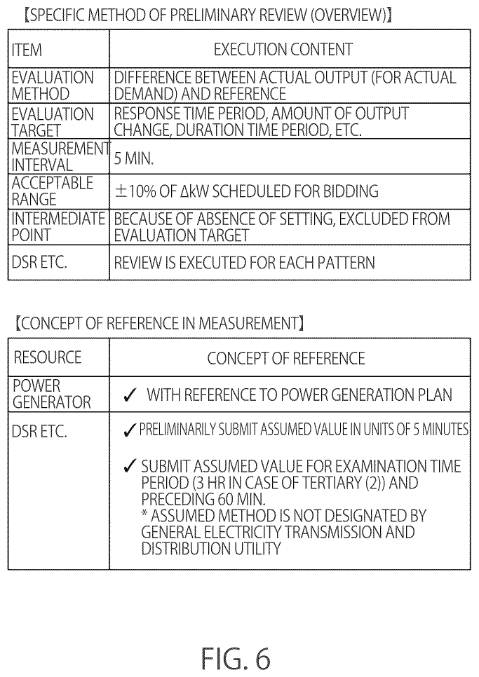

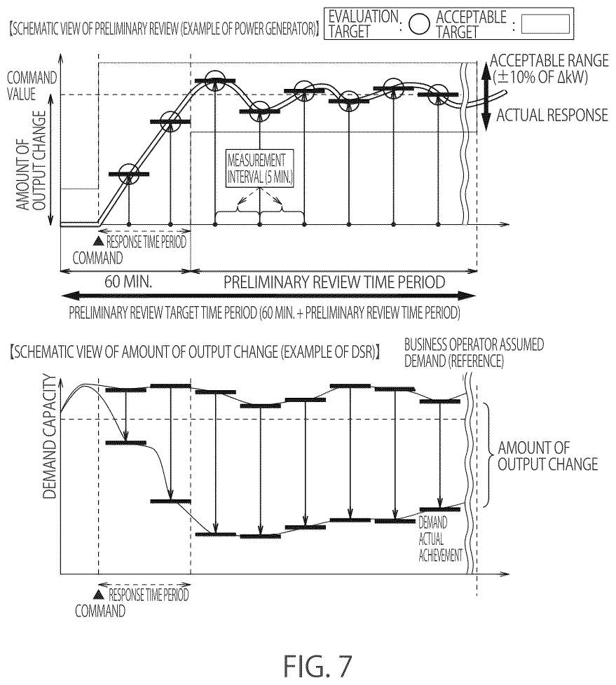

FIGS. 6 and 7 are diagrams for illustrating the preliminary review method for the tertiary adjustment capability [2]. FIGS. 6 and 7 are based on a material excerpted from the Material 3 of the 10-th Balancing Market Discussion Subcommittee.

“ΔKW SCHEDULED FOR BIDDING” in FIG. 6 corresponds to the contracted capacity.

As shown in FIG. 7, in a range of ΔkW value or less, in response to a power control instruction amount from the higher-level system, the power reduction amount for all the consumers is required to be adjusted within +10% of the ΔkW value in unit of 30 minutes. In other words, the difference between the target value (power in a case of adjustment of the control instruction amount from an after-mentioned reference value) and the average power value (30-minute value) of the entire consumers in unit of 30 minutes is required to be accommodated within +10% of ΔkW contracted capacity (in the case of the tertiary adjustment capability [2]; one-minute value is used in the case of the tertiary adjustment capability [1]).

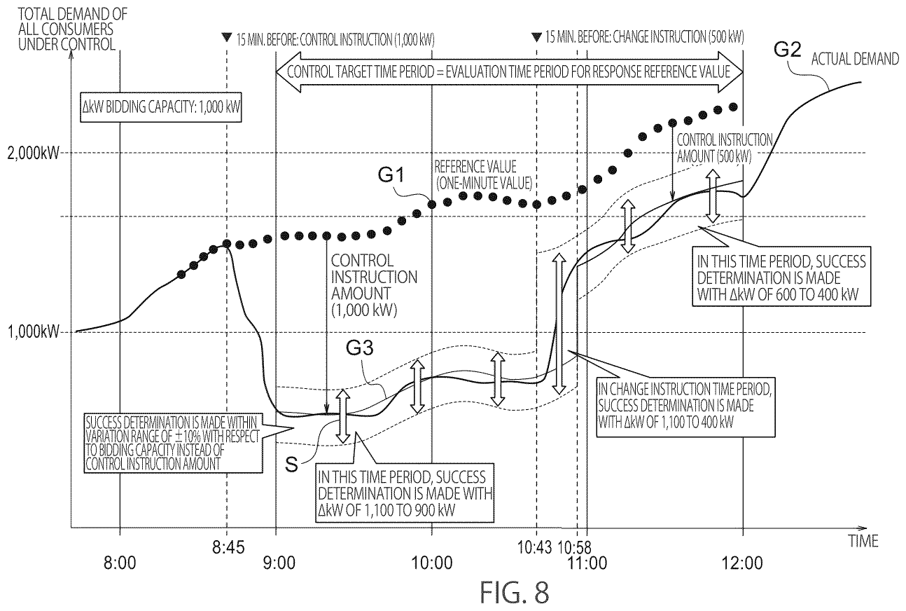

FIG. 8 is a diagram for illustrating an example of success determination in the tertiary adjustment capability [1]. FIG. 8 is based on a material excepted from FY 2020 VPP business common demonstration specifications. A graph G1 represents the reference value corresponding to an estimate (predicted value) of the demand capacity (power) of the entire consumers. A solid-line graph G2 represents the actual demand capacity (power). A graph G3 represents the control instruction amount. The reference value is the estimate (predicted value) of the demand calculated immediately before or a certain time period before a DR start instruction or a control instruction.

For example, in the case of the tertiary adjustment capability [1], an instruction of an actual control amount is provided 15 minutes before the control target time. In this case, as to the response evaluation, if the one-minute value (average power value in a minute) is accommodated within a width of +10% of ΔkW contracted capacity with respect to the target value (=reference value-control instruction amount), it is determined to be successful. In other words, if the demand reduction amount is between (control instruction amount+10% of contracted capacity) and (control instruction amount−10% of contracted capacity), it is determined to be successful.

In the illustrated example, the ΔkW contracted capacity is 1,000 kW. 10% of 1,000 kW is 100 KW. The control instruction is provided 15 minutes before control target time 9:00. The control instruction amount (reduction instruction amount) is 1,000 kW. If (reference value −1,000) kW is the target value, and the power value after demand adjustment by the aggregator is within +100 KW with respect to the target value, i.e., the demand reduction amount is between 1,100 and 900 kW, the determination result is successful. At a change instruction time (10:43) in a control target time period (9:00 to 12:00) corresponding to the commercial item block time period, a change instruction for the control amount with respect to the change target time (10:58) is provided. If the reduction amount of the one-minute average kW is accommodated within +10% of ΔkW contracted capacity with respect to the any of control instruction amounts before and after change, between the change instruction time and the change target time, it is determined to be successful.

A range in which the difference between the one-minute power value or the 30-minute power value of power and the target value is within +10% of ΔkW contracted capacity is assumed as a successful section S (see FIG. 8). In the case of the tertiary adjustment capability [1], the one-minute power value is used. In the case of the tertiary adjustment capability [2], the 30-minute power value is used. The ratio of a time period of residing in the successful section S in the control target time period is called a residence ratio. The residence ratio may be calculated any time unit (a five-minute unit, a unit of the control target time period, etc.). The response evaluation may be made in accordance with the residence ratio.

The overview of the present embodiment has thus been described assuming the balancing market practices that started FY 2021. Next, the overview of the present embodiment is described assuming a case of economic DR.

As described in https://www.jstage.jst.go.jp/article/ieejpes/139/10/139_NL10_10/_pd f/-char/ja, in current supply and demand operation, actors that are power generation and selling entities are required to achieve the planned value at the same time by the same amount in unit of 30 minutes by the electric power business operator. Accordingly, planned values for power generation and selling are required to be preliminarily designed. The achievement of the planned value at the same time by the same amount is to match the power generation plan with the demand plan. If there is a certain deviation or more between the planned value and the actual value, a fine called an imbalance fine is imposed in some cases. Consequently, when the demand assumption is changed, measures are often taken that procures required power, reviews the planned value accordingly in advance, and matches the actual value to the planned value. On the power generation side, it is determined whether to procure required power, based on power generator output adjustment, and transactions in the electricity exchange market (the wholesale electricity exchange market, time-ahead market, etc.) in consideration of economic advantages. On the other hand, on the selling side, if a reward to be paid for the consumer for demand adjustment is less expensive than the power procurement cost, demand is reduced (power saving) by the reward, which is less expensive than the market price, thus achieving an economic advantage on the selling side. Consequently, the demand can be reduced (balancing) on the selling side. This demand adjustment is called “economic DR”. For example, a case is assumed where with the original demand planned value of 1000 kWh, the demand planned value deviates upward to 1500 kWh. In this case, power procurement of 500 kWh from the electricity exchange market is required. However, if the apparent demand can be reduced by 100 kWh through power generation and discharge from rechargeable batteries, the procured power from the electricity exchange market can be reduced by 100 kWh to 400 kWh.

A problem of calculating the capability of how much the procurement capacity from the electricity exchange market can be reduced in the economic DR, i.e., how much the apparent demand can be reduced can be discussed with a framework equivalent to that of the balancing market in FIG. 1. The economic DR does not necessarily assume a higher-level system, such as DRAS, but is similar in that an obligation of achieving the planned value at the same time by the same amount is held. Measures of matching the actual demand with the planned value include two types that are procurement from the electricity exchange market, and procurement from the consumers (charge and discharge of storage batteries). Among them, inexpensive procurement from the consumers is assumed as bidding. Maximization of the procurement capacity from the consumers is an object of the economic DR. There are differences in that both evaluation intervals of achievement of the planned value at the same time by the same amount, and bidding intervals (hereinafter called blocks) are 30-minute intervals, in that unlike the balancing market, a direct incentive is not achieved by increasing the procurement capacity from the consumers, but an indirect incentive can be achieved by reducing the price for each block (price for procurement from the electricity exchange market), and in that the unit price for each block is possibly different.

Total three cases that are the case of the balancing market (preliminary review) described above, the case of the balancing market (actual evaluation), and the case of economic DR can be integrally dealt with by assuming the following variables.
The number of blocks (or unit time periods of blocks)
Price for each block
Evaluation unit (evaluation length)

In the case of the balancing market (preliminary review), the number of blocks: 1, and the block price: null, and the evaluation unit may be one minute for the tertiary adjustment capability [1], and five minutes for the tertiary adjustment capability [2].

In the case of the balancing market (actual evaluation), the number of blocks: 1, and the block price: null, and the evaluation unit may be one minute for the tertiary adjustment capability [1], and 30 minutes for the tertiary adjustment capability [2].

In the case of economic DR, the number of blocks: DR time period/30 minutes, and the block price: the price unit for procurement from the electricity exchange market, and the evaluation length may be 30 minutes.

The case of economic DR is different from the balancing market also in that no advantage is achieved even by increase and decrease beyond the original planned value. This point is described later.

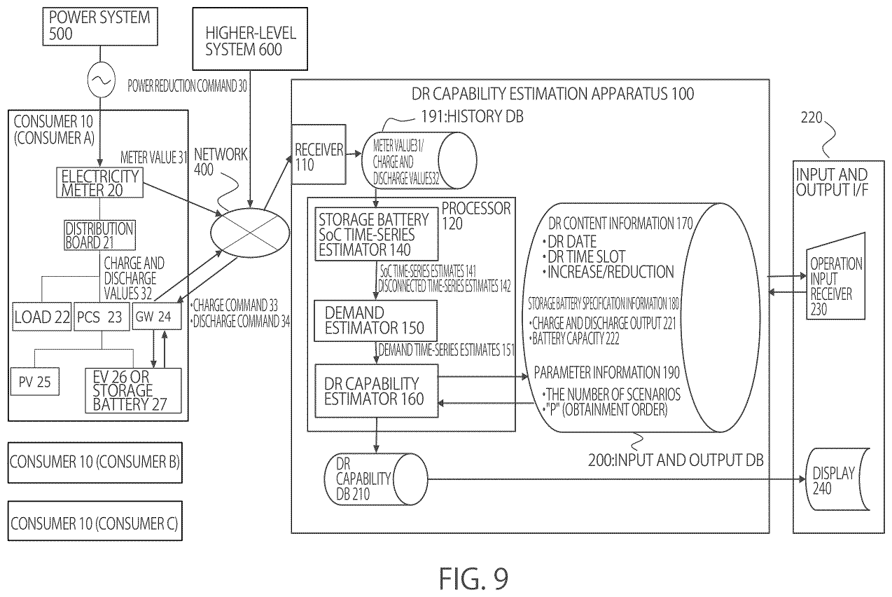

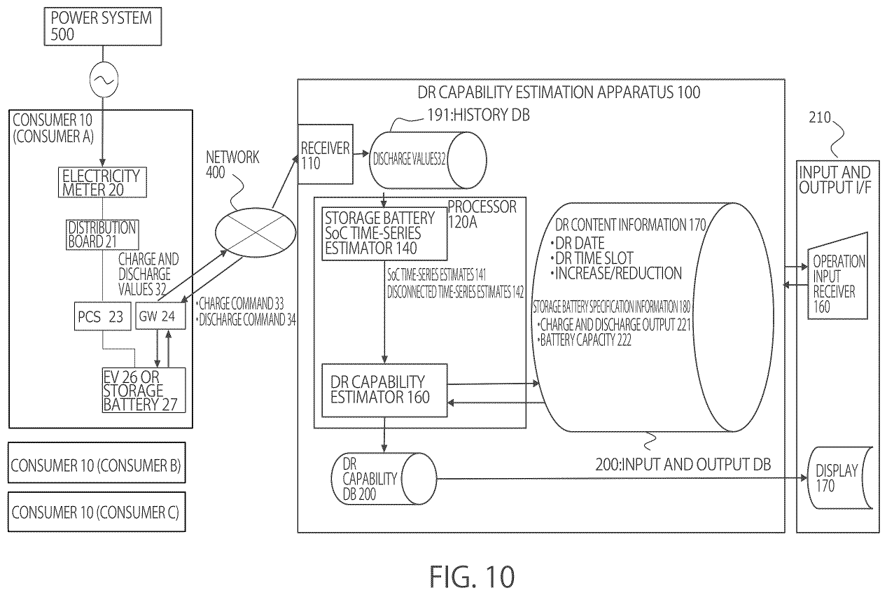

FIG. 9 is a block diagram showing in detail the configurations of the DR capability estimation apparatus 100 and the consumers 10 (consumers A, B, C, . . . ) according to the present embodiment. FIG. 9 also shows a power system 500 that the electric utility company 700 or the like includes, and the higher-level system 600, such as DRAS. Although only the configuration of the consumer A is shown, the consumers B, C, . . . and the like also have similar configurations. The configuration shown in FIG. 9 is only an example. Some of the components shown in FIG. 9 may be absent. Additional components may be present. For example, FIG. 10 is an example of a block diagram of a configuration (for convenience, called a simplified configuration) that is the configuration shown in FIG. 9 but some components are omitted.

In FIG. 9, a receiver 110 of the DR capability estimation apparatus 100 obtains a meter value 31 every one minute, and a charge/discharge value 32 every minute (at least one of a charge value and a discharge value), from each consumer 10 via a communication network 400. The communication network 400 may be a wide area network, such as the Internet, a local area network, or a private network. The receiver 110 receives a power reduction command 30 (a DR command or a control command) from the higher-level system 600, via the communication network 400. Upon receipt of the power reduction command 30, a processor 120 of the DR capability estimation apparatus 100 estimates a DR capability described later.

Note that the processor 120 of the DR capability estimation apparatus 100 may have a charge and discharge plan creating function. In this case, the processor 120 creates a charge and discharge plan for each consumer, based on the meter value 31 every minute, and the charge/discharge value 32 every minute, for example, in the DR time period, and transmits a charge command 33 or a discharge command 34 to each consumer 10. Creation of the charge and discharge plan, and transmission of the charge command 33 or the discharge command 34 are performed at an interval of a certain time period (e.g., every five minutes), for example. The storage battery 27 of the consumer 10 having received the charge command 33 or the discharge command 34 performs charging or discharging at a predetermined charge power value or a predetermined discharge power value. The configuration and operation of the charge and discharge plan creating function are not essential characteristics of the present embodiment. Accordingly, more detailed description is omitted.

The consumer 10 is supplied with power from the power system 500. The supplied power is supplied to a load 22 through a distribution board 21. The electric energy supplied from the power system 500 is measured by an electricity meter 20 every minute, for example. The storage battery 27, an electric vehicle (EV) 26, a photovoltaic (PV) panel 25 and the like are connected to the distribution board 21 via a PCS 23. The storage battery 27 may be part of the EV 26.

The storage battery 27 and the electric vehicle (EV) 26 can receive at least one of signals from the outside, e.g., the charge command 33 and the discharge command 34, via a gateway (GW) 24, such as HEMS. The storage battery 27 can execute charging or discharging, based on the charge command 33 or the discharge command 34. The storage battery 27 can transmit the charge/discharge value 32 indicating the charged or discharged electric energy, to the DR capability estimation apparatus 100 via the gateway 24.

The electricity meter 20 transmits the measured meter value 31 to the DR capability estimation apparatus 100. The electricity meter 20 transmits the meter value 31, not through the gateway 24. Note that a configuration of transmitting the meter value 31 through the gateway 24 can be adopted.

The DR capability estimation apparatus 100 includes the receiver 110, the processor 120, an input and output DB 200, a history DB 191, and a DR capability DB 210. The processor 120 includes a storage battery SoC time-series estimator 140, a demand estimator 150, and a DR capability estimator 160. The processor 120 may be configured by processing circuitry such as a CPU or a dedicated circuit. The input and output DB 200 stores DR content information 170, battery specification information 180, and parameter information 190.

The DR capability estimation apparatus 100 is wiredly or wirelessly connected to an input and output I/F 220 with a user, i.e., an operator of this apparatus 100. The input and output I/F 220 may be connected to the DR capability estimation apparatus 100 via the communication network 400. The input and output I/F 220 includes an operation input receiver 230, and a display 240. The operation input receiver 230 is a device that receives information or data from a keyboard, a mouse, a touch panel, an audio input device, a gesture input device, etc. The display 240 is a device that displays information or data on a screen, such as a liquid display device, or an organic EL display device.

The operation input receiver 230 has a function of receiving information to be stored in the input and output DB 200. For example, the input and output DB 200 may download data from any external device, based on user's instruction information from the input and output I/F 220, and store the data in the input and output DB 200. The display 240 has a function of displaying information in the input and output DB 200, or information in the DR capability DB 210. The display 240 may have a function of displaying the information in the DR capability DB 210, or data based on this information.

The receiver 110 receives the meter value (measurement) 31, and the charge/discharge value 32, from each consumer 10 via the communication network 400. For example, the meter value 31 or the charge/discharge value 32 are received every minute. The receiver 110 stores the received meter value 31 and charge/discharge value 32, in the history DB 191. The history DB 191 stores the history of the charge/discharge value 32 in a first period, and the history of the meter value 31 in a second period. The first period and the second period may be identical to or different from each other. The receiver 110 receives the power reduction command 30, i.e., an example of the control command, from the higher-level system 600.

The storage battery SoC time-series estimator 140 calculates an SoC time-series estimates 141 of each consumer, by estimating the time series of the storage battery SoC of each consumer, based on the charge/discharge value 32 stored in the history DB 191. The estimation target time slot corresponds to, for example, the second period that is a DR time slot. Note that the present embodiment assumes that the DR time slot, which is the estimation target, is a time slot in the future. However, estimation for a time slot in the past is not excluded. Note that the estimation in a time slot in the future may be specifically called prediction.

The storage battery SoC time-series estimator 140 estimates a time period during which the EV 26 (or storage battery 27) is not connected to household premises, and calculates the disconnected time-series estimates 142. Estimation is performed for, e.g., the DR time slot (second period) as a target. In a case where no EV 26 is connected to the household premises, the storage battery in the EV 26 cannot be used during balancing. The state where no EV 26 is connected to the household premises means that the storage battery in the EV 26 is not connected to the power system (PCS 23) in the household premises in a rechargeable and dischargeable manner. According to the present embodiment, the time period during which no EV 26 (or storage battery 27) is connected to the household premises is estimated. Alternatively, a time period of connection to the household premises may be estimated. A time period of connection or disconnection to the household premises may be described as a connected/disconnected time period.

The demand estimator 150 obtains demand time-series estimates 151 of each consumer by estimating the time series of power demand (power demand) of the corresponding consumer, based on the meter value 31 stored in the history DB 191. Estimation is performed for, e.g., the DR time slot as a target. The method of estimation may be similar to that of estimation of the SoC time-series estimates 141 and the disconnected time-series estimates 142. Alternatively, the demand value may be estimated by regression analysis based on the meter value 31. Here, the meter value of the total of the demand value and the charge and discharge capacities is measured by the electricity meter 20 in some cases. In such cases, the charge and discharge capacities of the storage battery are not included in the calculated demand value. Accordingly, the demand value may be obtained by subtracting the charge capacity of the storage battery from and adding the discharge capacity to the value measured by the electricity meter 20 (see Expression (1) and Expression (2) described later).

The DR capability estimator 160 estimates the DR capability that is the power adjustable capacity in the case of using the storage batteries 27 of the consumers, based on the demand time-series estimates 151, the SoC time-series estimates 141, and the disconnected time-series estimates 142, and stores the estimated DR capability in the DR capability DB 210. The DR capability (power adjustable capacity) corresponds to the total of the rechargeable capacities or the dischargeable capacities of the storage batteries of the consumers (a case of storage batteries mounted on EVs is included).

Here, a publicly known method may be used for algorithms for operations of the storage battery SoC time-series estimator 140 and the demand estimator 150, on a consumer-by-consumer basis. In a simple manner, a “k”-day previous demand actual value or SoC actual value themselves may be respectively adopted as the demand time-series estimates 151 and the SoC time-series estimates 141. Alternatively, a method of shifting the actual value by a certain value may be used. The estimate may be calculated using attributes of a day, such as a weekday or a holiday, or information on weather, temperature, etc. In an after-mentioned example of using a plurality of prediction scenarios, demand and SoC actual values on days among several previous days themselves may be used as the demand time-series estimates 151 and the SoC time-series estimates 141. Alternatively, a method of restoring or estimating past achievement that does not exist (fictional achievement) based on actual achievement that actually exists may be used. As for the disconnected time-series estimates 142, for example, a connection history of EVs is preliminarily stored, and the “k”-day previous actual value itself may be assumed as the disconnected time-series estimates 142. A method of shifting the actual value by a certain value may be used. The estimate may be calculated using attributes of a day, such as a weekday or a holiday, or information on weather, temperature, etc. In an after-mentioned example of using a plurality of prediction scenarios, actual values of presence or absence of connection in days among several previous days themselves may be used as the disconnected time-series estimates 142. Alternatively, a method of restoring or estimating past achievement that does not exist (fictional achievement) based on actual achievement that actually exists may be adopted.

Note that a method of data transmission and reception via a network by the receiver 110, and a method of inputting and outputting data to and from the input and output DB 200 are not specifically limited in the present embodiment. Hereinafter, data about input and output of the DR capability estimator 160 is described in detail.

### [SoC Time-Series Estimates 141 and Disconnected Time-Series Estimates 142]

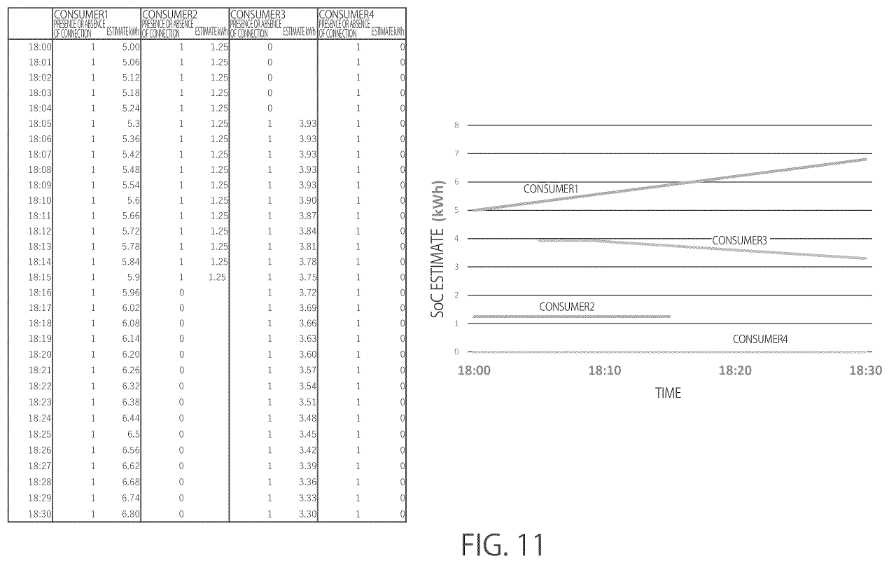

Referring to FIG. 11, details of the SoC time-series estimates 141 and the disconnected time-series estimates 142 that the storage battery SoC time-series estimator 140 creates are described. The left diagram of FIG. 11 shows an example of the SoC time-series estimates 141 and disconnected time-series estimates 142. The right diagram of FIG. 11 shows an example of data of SoC estimates of individual consumers as graphs. Time periods in which no graph is present means that no storage battery is connected. The disconnection of the storage battery encompasses cases where no EV is connected.

FIG. 11 shows the disconnected time-series estimates 142 that represent estimation of presence or absence of connection of the individual consumers in 30 minutes between 18:00 and 18:30, every minute (one in the case of connection, and zero in the case of disconnection), and the SoC time-series estimates 141 that represent the estimated SoC (unit of kWh) of storage batteries of the individual consumers, every minute. If the storage battery is the storage battery of the EV, the case where no EV is present, and the case of being mistakenly left disconnected indicate disconnection. Possible occurrence of an event of connection or disconnection of the EV in the DR time slot greatly affects the DR capability. Accordingly, the disconnected time-series estimates 142 are important. For the storage batteries connected to the household premises or the like, various types of charge and discharge control are autonomously performed based on setting on the household side. For example, setting of operating an air conditioner in a specific time slot, and setting of boiling water in a specific time slot are configured in some cases. Consequently, an operation of starting or finishing charging or discharging at a predetermined time, or a certain time period after the EV reaches the household premises of the consumer sometimes occurs.

In this example, for a consumer 1, SoC is 5.00 kWh at the time point of 18:00, and subsequently, the SoC estimate increases by 0.06 kWh (=3.6 kW) every minute (i.e., after the time point of 18:00, the storage battery is continuously charged). For a consumer 2, the SoC is constant at 1.25 kWh until 18:15. After 18:15, the storage battery is disconnected (for example, no EV is present). For a consumer 3, until 18:05, the storage battery is disconnected (for example, no EV is present). At 18:05, the storage battery with SoC of 3.93 kWh is connected. After 18:10, the SoC estimate decreases by 0.03 kWh every minute (=1.8 KW) (i.e., after 18:10, the storage battery is continuously discharged).

### [Demand Time-Series Estimate 151]

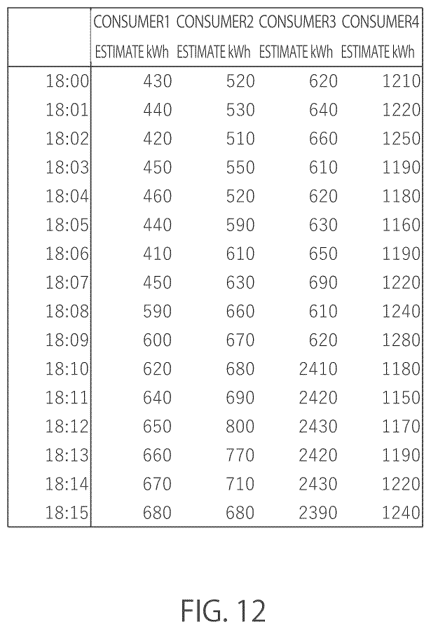

Referring to FIG. 12, the details of the demand time-series estimates 151 that the demand estimator 150 creates are described. FIG. 12 shows an example of the demand time-series estimate 151.

Here, the demand estimates of the consumer (unit of Wmin) in 15 minutes between 18:00 and 18:15 are indicated every minute. For demand, there is basically no missing data. At every time, a value is indicated. Note that the value of demand can be obtained by the following method. The meter value that integrally includes the demand value and the charge and discharge capacities is measured. Accordingly, the following relational expression holds.

Meter value=demand+charge capacity−discharge capacity (1)

Consequently, the demand value can be obtained by the following relational expression.

Demand=meter value−charge capacity+discharge capacity (2)

### [DR Content Information 170]

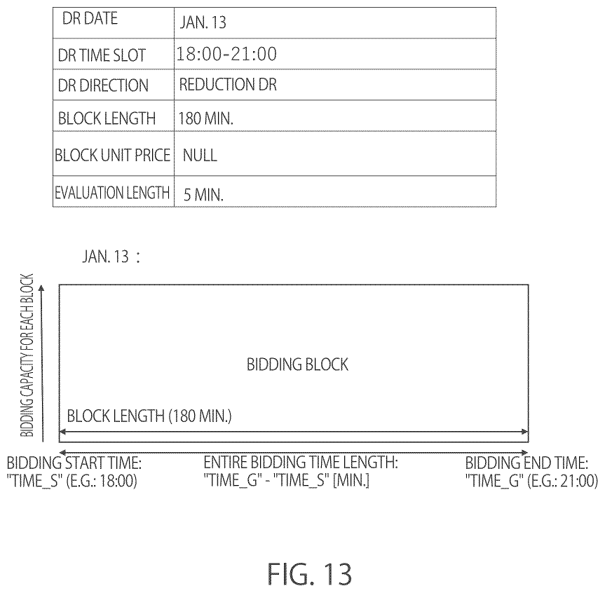

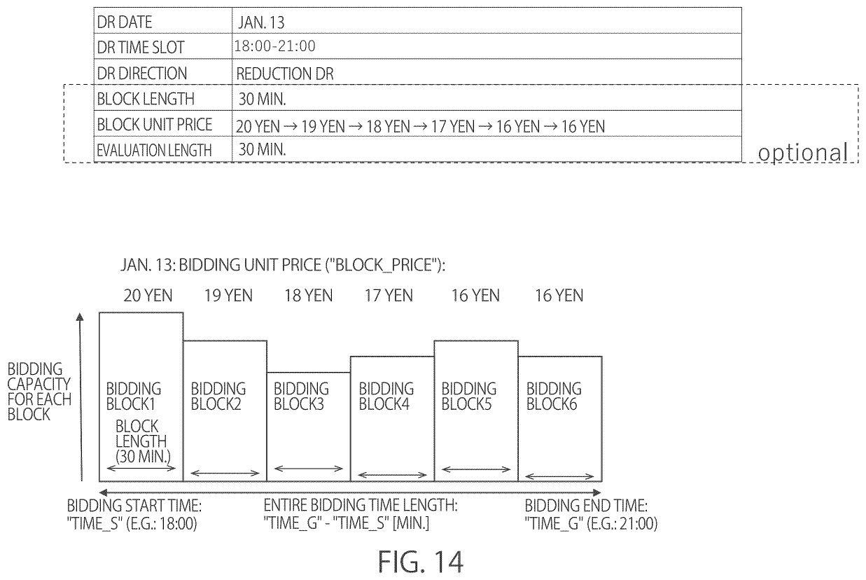

Referring to FIGS. 13 and 14, the details of the DR content information 170 in the input and output DB 200 are described.

FIG. 13 shows an example of the DR content information 170 in the case of the balancing market. The DR content information 170 includes information on the DR date, time slot, distinction between increase and reduction, block length, evaluation length, and block unit price.

Here, a case is shown where between 18:00 and 21:00 on January 13, reduction DR is issued, and the block length is designated as three hours. The DR content information is not on DR that has been actually issued, and has content of DR designated (input) by the user assuming forthcoming occurrence. Here, the block is a time unit for bidding. In a case where the block length is 180 minutes, it is required to calculate the bidding capacity every 180 minutes. In the case of the balancing market, a bid for one bidding capacity is made for the entire three hours. Accordingly, the number of blocks is necessarily one. Accordingly, the block length is 180 minutes, which corresponds to the entire DR time slot. The evaluation length is five minutes. In this case, the power every five minutes is accommodated in an acceptable range with respect to the target value (=reference value-command value (control instruction amount)) (adjusted in a range of +10% from the target value) constitutes the success condition. Here, the case where the DR direction is “reduction” is described. In the case of “increase”, the target value is the reference value+the command value.

FIG. 14 shows an example of the DR content information 170 in the case of the economic DR. Here, a case is shown where between 18:00 and 21:00 on January 13, reduction DR is issued, and the block length is designated as 30 minutes (or the number of blocks is six). The DR content information is not on DR that has been actually issued, and has content of DR designated (input) by the user assuming forthcoming occurrence.

In the case where the block length is 30 minutes, the DR capability may be calculated for each of six blocks obtained by dividing three hours from 18:00 to 21:00 by 30 minutes. Furthermore, in this case, block unit prices are set for the respective blocks, the DR capabilities that maximize the summation of products of bidding capacities of the individual blocks and the respective unit prices are calculated.

Note that in the economic DR, the case of issuance of “reduction DR” corresponds to a case where the actual value probably deviates upward from the planned value. In this case, if the planned value is exceeded, a fee for procurement from the electricity exchange market should be paid. On the other hand, if the power can be reduced to the planned value, the fee is not required to be paid. Accordingly, the procurement unit price can be regarded as the block unit price.

### [Storage Battery Specification Information 180]

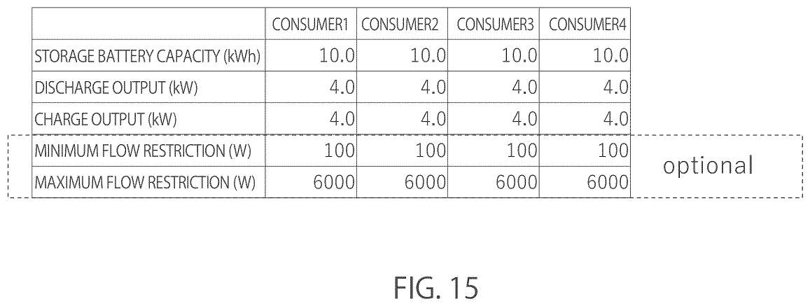

Referring to FIG. 15, the details of the storage battery specification information 180 in the input and output DB 200 are described. FIG. 15 shows an example of the storage battery specification information 180.

The storage battery specification information 180 includes the capacity, discharge output, charge output, a minimum flow restriction (or a minimum meter restriction), and maximum flow restriction (or a maximum meter restriction). Here, the capacity of each of the storage batteries of the consumers 1 to 4 is 10.0 kWh, the discharge output and the charge output are 4.0 kW, the minimum flow restriction is 100 W, and the maximum flow restriction is 6000 W. The flow restriction is a restriction on the value of the electricity meter 20. The meter value 31 of the electricity meter 20 is required to be equal to or higher than 100 W and equal to or lower than 6000 W. The minimum flow restriction has a positive value. Accordingly, the reverse power flow is prohibited. To permit the reverse power flow, the minimum flow restriction is set to a negative value.

### [Details of Charge and Discharge Available Capability Calculation]

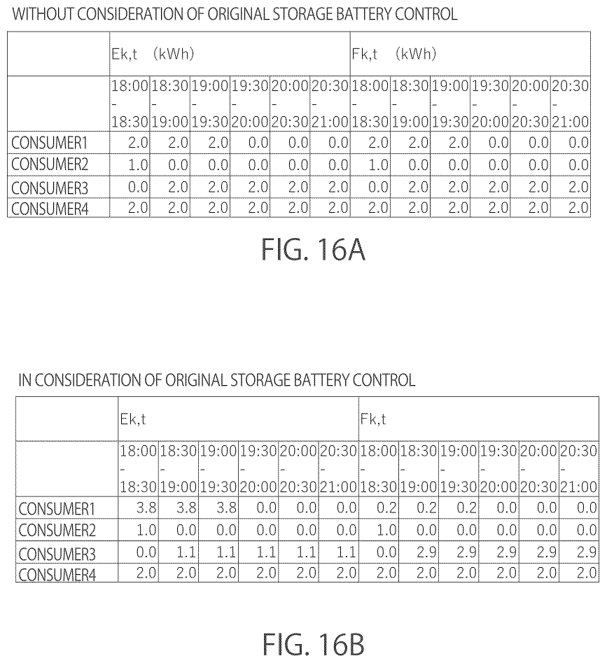

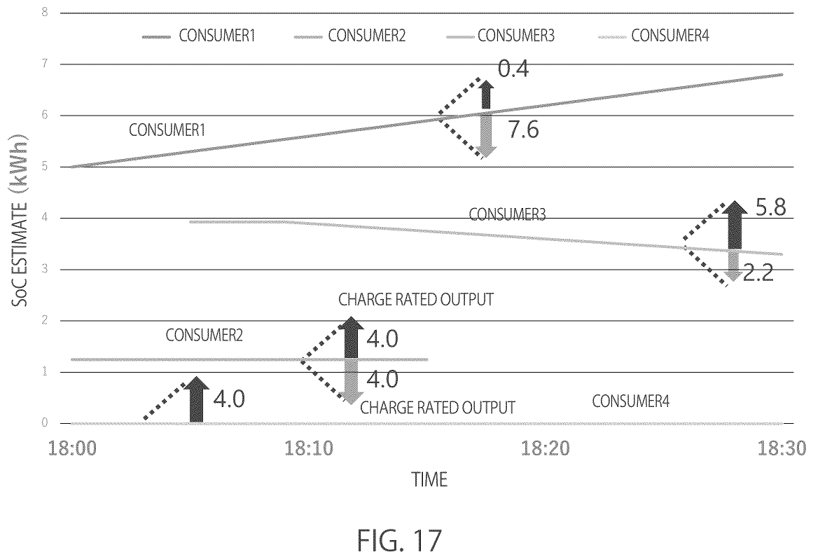

The discharge output and the charge and discharge output themselves shown in FIG. 15 described above are values that do not depend on the time. However, depending on presence or absence of connection to the storage batteries at each time, and presence or absence of control preset for the storage batteries (original storage battery control), the apparent rechargeable and dischargeable capacities temporally vary. Accordingly, the details of the apparent rechargeable and dischargeable capacities are described referring to FIGS. 16 and 17. An example is described where depending on presence or absence of the original storage battery control for the storage batteries, the apparent rechargeable and dischargeable capacities temporally vary.

FIG. 16A shows an example of a calculation result of rechargeable and dischargeable capacities in a case without consideration of the original storage battery control. The dischargeable capacity and the rechargeable capacity of the consumer “k” at time “t” are assumed as “E_{k,t}” and “F_{k,t}”, respectively.

First, an example is described where with respect to presence or absence of connection to the storage batteries, the apparent rechargeable and dischargeable capacities temporally vary.

In the case of an estimation result in FIG. 11 described above, for the consumer 3, the storage battery is connected on and after 18:05. Provided that presence or absence of connection to the storage battery (e.g., presence or absence of the EV) is determined in unit of 30 minutes in this case, it is configured that charge and discharge are set disabled until 18:30. Accordingly, as shown in FIG. 16A, “E_{k,t}” (dischargeable capacity) from 18:00 to 18:30 is 0, and “E_{k,t}” on and after 18:30 is 2.0.

Likewise, for the consumer 2, the storage battery becomes disconnected on 18:16 (see FIG. 11). Provided that presence or absence of connection to the storage battery (e.g., presence or absence of the EV) is determined in unit of 30 minutes also in this case, discharge is disabled in all the time slots. Conversely, if logic of enabling discharging until immediately before disconnection is used here, “E_{k,t}” of the storage battery of the consumer 2 from 18:00 to 18:30 is 1.0 as in FIG. 16A. Note that the value is 2 kW, and is used for 15 minutes in the entire 30 minutes. It is thus calculated as 1.0 kW according to 2×15/30. Note that also for the consumer 3, logic similar to that for the consumer 2 is used, i.e., logic of enabling discharging from connection at 18:05 to 18:30, the dischargeable capacity can be calculated.

For the consumers (consumers 1 and 4) other than the consumers described above, in the time slot in unit of 30 minutes, connection is constantly established or is not established.

Consequently, for the consumers 1 and 4, “E_{k,t}” and “F_{k,t}” have a non-zero value only in the connected time slot, and “E_{k,t}” and “F_{k,t}” have a value of zero in the disconnected time slot.

FIG. 16B shows an example of a calculation result of rechargeable and dischargeable capacities in a case of consideration of the original storage battery control. FIG. 17 is a supplementary explanation diagram of calculation of rechargeable and dischargeable capacities in consideration of the original storage battery control. As schematically shown in FIG. 17, in the case where the original storage battery control is present, the value increases or decreases from the rated output by the corresponding amount. Accordingly, the apparent rechargeable and dischargeable capacities are required to be calculated.

For the consumer 1, continuous charging with 3.6 kW from 18:00 to 19:30 is assumed (see FIG. 11). Consequently, in the time slot during which charging is assumed to be performed, the apparent available dischargeable capability is 7.6 kW, which is larger than the rated one by 3.6 kW, and the available rechargeable capability is 0.4 KW, which is smaller than the rated one by 3.6 kW.

On the other hand, for the consumer 3, continuous discharging with 1.8 kW after 18:10 is assumed (see FIG. 11). Accordingly, the apparent available dischargeable capability is 2.2 kW, which is smaller than the rated one by 1.8 kW, and the available rechargeable capability is 5.8 KW, which is larger than the rated one by 1.8 kW.

For the consumer 2, in the time slot from 18:00 to 18:15 during which the storage battery is assumed to be connected, the original storage battery control is absent. Accordingly, both the available rechargeable capability and the available dischargeable capability coincide with the rated output of 4.0 kW.

For the consumer 4, the original storage battery control is absent for the storage battery, and the SoC estimate is zero. Accordingly, only charging is allowed, and the available rechargeable capability coincides with the rated output of 4.0 kW.

According to the above description, in the case of consideration of presence or absence of the original storage battery control in addition to the presence or absence of connection to the storage battery, the values shown in FIG. 16B are adopted as “E_{k,t}” and “F_{k,t}”. Here, it should be noted that kWh in 30 minutes is ½ of the kW value. For example, “E_{k,t}” from 18:00 to 18:30 for the consumer 1 is calculated as 7.6 kW. However, FIG. 16B has representation in unit of kWh. Accordingly, a value of 3.8 corresponding to 3.8 kWh equal to 7.6 kW is described. Note that since calculation of these “E_{k,t}” and “F_{k,t}” uses SoC estimates and disconnect estimates as time series after DR start time (since the estimate at the DR start time is not commonly applied to the DR time slot), the calculation accuracy of the DR capability can be improved.

It varies whether the original storage battery control is effectively set in the DR time slot, depending on the consumers. Accordingly, in accordance with the situation or setting of the consumer, the schemes of FIGS. 16(A) and 16(B) may be differently used. For example, if the consumer uses setting of canceling the original storage battery control in the DR time slot, the scheme in FIG. 16A may be used. Information on whether the original storage battery control is performed in the DR time slot or not with respect to each consumer may be stored in the input and output DB 200.

### [Parameter Information 190]

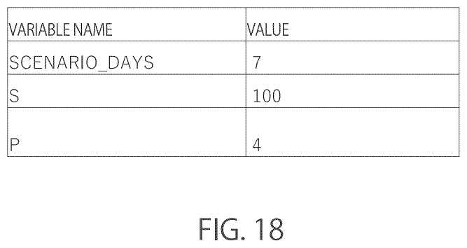

Referring to FIG. 18, the parameter information 190 in the input and output DB 200 is described. FIG. 18 shows an example of the parameter information 190. The parameter information 190 is parameters used in a case where the DR capability estimator 160 estimates the DR capability using a plurality of scenarios. The parameter information 190 includes, for example, the number “S” of scenarios used for estimation, the number of days “SCENARIO_DAYS” of previous data used to create the scenario, and a value “P” indicating what number of the estimation result is selected when the estimation results of the respective scenarios are sorted in a descending or ascending order. The details of each parameter are described later.

### [DR Capability DB 210]

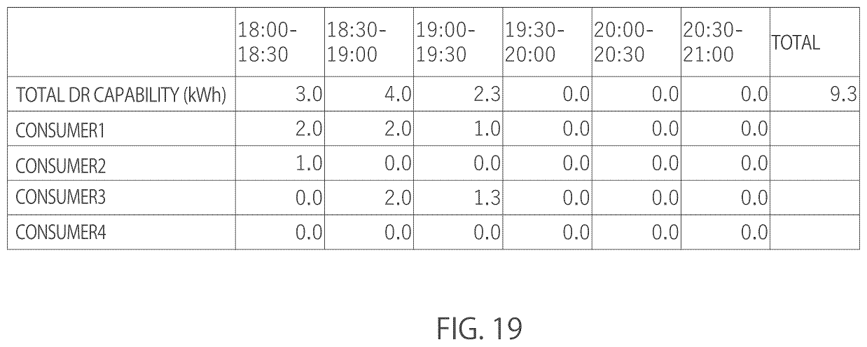

Referring to FIG. 19, the DR capability DB 210 that stores DR capability information that is the output of the DR capability estimator 160 is described. The details of operation of the DR capability estimator 160 are described later. FIG. 19 shows an example of the DR capability DB 210.

Here, the total DR capability (power adjustable capacity) of all the consumers for each of blocks from 18:00-18:30 to 20:30-21:00, and the breakdown of each consumer are indicated in kWh (since each cell is in every 30 minutes, the value becomes twice when represented in average kW). For example, the total DR capability from 18:00 to 18:30 is 3.0 kWh. The breakdown indicates that the consumer 1 is 2.0 kWh, and the consumer 3 is 1.0 kWh.

Hereinafter, operation examples of the DR capability estimator 160 are described as Embodiments 1 to 5.

### Embodiment in the Case of Reduction DR with the Simplified Configuration Shown in FIG. 10: Embodiment 1

Here, the embodiment is described where with the simplified configuration in FIG. 10, the DR capability estimator 160 receives the SoC time-series estimates 141, the disconnected time-series estimates 142, the storage battery specification information 180, and the DR content information 170, as inputs, estimates the DR capability, and stores information on the estimated DR capability in the DR capability DB 210.

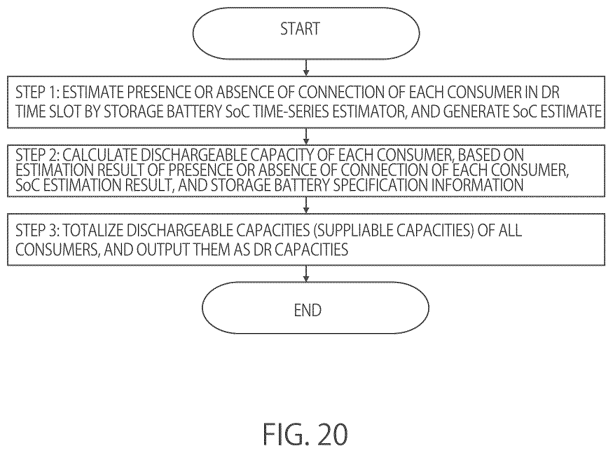

FIG. 20 is a flowchart of processes of the simplified configuration in FIG. 10.

First, in Step 1, the storage battery SoC time-series estimator 140 performs estimation of presence or absence of connection and estimation of SoC in the DR time slot for each consumer, and generates the SoC time-series estimates 141 that represents SoC estimation results of the storage battery of each consumer, and the disconnected time-series estimates 142 that represent estimates of presence or absence of connection of the storage battery of each consumer.

Next, in Step 2, the DR capability estimator 160 calculates the dischargeable capacity (suppliable capacity) of each consumer for each block, based on the SoC time-series estimates 141 and the disconnected time-series estimates 142. The power discharged as described above can sometimes be used in household premises, and can sometimes be supplied to outside of the consumer household premises (provided for a buyer).

Lastly, in Step 3, the DR capability estimator 160 totalizes the dischargeable capacities of all the consumers on a block-by-block basis, and outputs the total as the DR capability (power adjustable capacity).

Hereinafter, as a specific example, the details of Step 2 in FIG. 20 in a case where the SoC time-series estimates 141 and the disconnected time-series estimates 142 in FIG. 11, the storage battery specification information 180 in FIG. 15, and the DR content information 170 in FIG. 14 are received as inputs is described.

First, for the consumer 1, the SoC estimation result at 18:00 is 5.0 kWh, and the discharge output (maximum value) is 4.0 kW. Accordingly, it is shown that if the discharge output is continued with the maximum of 4.0 KW (2.0 kWh in 30 minutes), a continuous duration of an hour and 15 minutes is allowed. Consequently, if the DR capable output is calculated every 30 minutes, power of 2.0 kWh can be discharged in blocks of 18:00-18:30 and 18:30-19:00, and power of 1.0 kWh can be discharged in the block of 19:00-19:30.

Next, for the consumer 2, the SoC estimate at 18:00 is 1.25 kW, but the connection is disengaged at 18:15. Accordingly, discharge is allowed only in the first 15 minutes. Since the discharge output (maximum value) is 4.0 kW, power of 1.0 kWh can be discharged in 15 minutes. Note that calculation is made assuming that the connection is securely engaged until 18:15. However, if the connection is probably disengaged before 18:15, discharging may be regarded not to be allowed, and the dischargeable capacity may be 0 kWh.

Next, it is expected that the consumer 3 is absent at 18:00. Accordingly, discharging is not allowed until 18:30. In this case, the dischargeable capacity until 18:00 to 18:30 is 0 KW. On the other hand, the SoC estimate at 18:30 is 3.3 kWh. Accordingly, if the maximum discharge output of 4 kW is continued, 2.0 kWh can be discharged in the first block from 18:30 to 19:00, but only the remaining 1.1 kWh can be discharged in the next block from 19:00 to 19:30.

Next, for the consumer 4, the estimation result indicates continuous connection at and after 18:00, but the SoC estimation result is 0 kW. Accordingly, the dischargeable capacity is 0 kWh.

The summary of the above results is the DR capability information in FIG. 19 described above.

In Step 3, the DR capability estimator 160 totalizes the values of the consumers on a block-by-block basis, thus obtaining the total DR capability of all the consumers as shown in FIG. 19. That is, the total DR capability is 3.0 kWh, 4.0 kWh, 2.3 kWh, 0 kWh, 0 kWh, and 0 kWh in the order of blocks.

According to the method described above, also in the case where the storage battery (e.g., EV-mounted storage battery) is possibly disconnected from the power system, the DR capabilities (dischargeable capacities) of one or more consumers can be calculated.

### Embodiment in Case of Increase DR: Embodiment 2

With Embodiment 1, the case of reduction DR is described. With Embodiment 2, the case of increase DR is described. In the case of increase DR, the remaining capacity of the storage battery is defined as “capacity value-SoC estimate” (“−” represents subtraction). If the discharge output in the description of Embodiment 1 is replaced with the charge output, the DR capability can be estimated by a process similar to that in Embodiment 1. Hereinafter, an example of calculating the DR capability in the case of increase DR is described. The increase DR time slot is assumed as 18:00-21:00.

For the consumer 1, the available increase capability (available rechargeable capability) at 18:00, i.e., the remaining capacity of the storage battery is calculated as 10.0-5.0=5.0 kWh by “capacity value-SoC estimate at 18:00”. Since the charge output (maximum value) is 4 kW, the chargeable duration time period is (5.0/4.0=1.25 h=) one hour and 15 minutes.

For the consumer 2, it is assumed that connection is established only until 18:00 to 18:15. Accordingly, similar to the case of the reduction DR, the rechargeable capacity is 1 kWh.

For the consumer 3, the available increase capability at 18:30 is calculated as 10.0-3.3=6.7 kWh by “capacity value-SoC estimate at 18:30”. Since the charge output (maximum value) is 4.0 kW, the chargeable duration time period is (6.7/4.0=) 1.675 h, i.e., about one hour and 40 minutes.

On the other hand, for the consumer 4, the available increase capability at 18:00 is calculated as 10.0-0.0=10.0 kWh by “capacity value-SoC estimate at 18:00”. Since the charge output (maximum value) is 4.0 kW, continuous charging from 18:00 to 20:30 can be achieved.

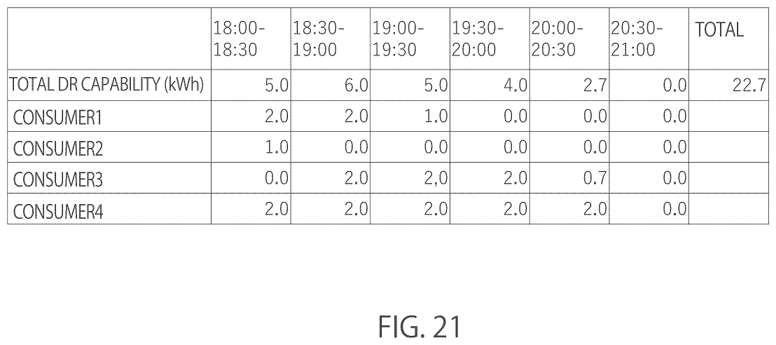

The summary of the calculation results described above is shown in FIG. 21.

FIG. 21 shows the DR capability information in the case of increase DR. For each block, the DR capability (rechargeable capacity) of each consumer, and the total DR capability are shown. That is, the total of the DR capabilities of all the blocks, i.e., the DR capability in all the DR time slots is shown.

According to the method described above, also in the case where the storage battery (e.g., EV-mounted storage battery) is possibly disconnected from the power system, the DR capabilities (here, rechargeable capacities) of one or more consumers can be calculated.

### Embodiment in Case of Economic DR Maximizing Revenue by Bidding on a Block-by-Block Basis: Embodiment 3

With Embodiments 1 and 2, the method of DR in a forward-aligning manner by charging or discharging at the possible maximum output by all the consumers, for each of blocks obtained by dividing the time slot is described. Here, an embodiment is described where unit prices for the respective blocks are defined, and the summation of bidding capacity x unit price is maximized.

In the case of reduction DR, this problem can be represented also as an optimization problem as described below (in the case of increase DR, “−I_{b(t)}” in the following Expression (4) may be replaced with “I_{b(t)}”). Note that the power charged or discharged here is discharged or recharged in any following stage. Accordingly, the power purchase unit price at the time is ignored. However, if the balance only in this time slot is considered, the value of “Pb” can be regarded as bidding unit price+power purchase unit price, in the discharging case (because the purchased power capacity is reduced by discharging), and as bidding unit price−power purchase unit price, in the charging case (because the purchased power capacity is increased by charging).

In the case of economic DR, the object is approach to the planned value. Thus, charging and discharging beyond the planned value have no meaning. Accordingly, upper and lower limit restrictions indicating that the planned value should not be exceeded may be imposed on “I_{b}”. Note that the planned value is not reached even by full charging and discharging in many cases. Accordingly, there is no problem in many cases even if the upper and lower restrictions are omitted.

$$max {\sum }_{b ∈ B} {P}_{b} {I}_{b} \qquad ( 3 )$$

$$s . t . - {E}_{k , t} {x}_{k , t} + {F}_{k , t} {z}_{k , t} = - {I}_{b ( t )} , ∀ t ∈ T , \qquad ( 4 )$$

$$- {A}_{k} \leq {\sum }_{t \leq {t}^{′}} - {E}_{k , t} {x}_{k , t} + {F}_{k , t} {z}_{k , t} + {G}_{k , t} \leq {C}_{k} , ∀ k ∈ K , ∀ {t}^{′} ∈ T , \qquad ( 5 )$$

$$0 \leq {x}_{k , t} \leq 1 , 0 \leq {z}_{k , t} \leq 1 , ∀ k ∈ K , ∀ t ∈ T . \qquad ( 6 )$$

Variable
   “X_{k,t}”: a continuous variable that is one when a discharge request at the maximum output is issued to the consumer “k”∈“K” at time “t”∈“T”, and is zero when no discharge request is issued
   “Z_{k,t}”: a continuous variable that is one when a charge request at the maximum output is issued to the consumer “k”∈“K” at time “t”∈“T”, and is zero when no charge request is issued
   “I_{b}”: bidding capacity of block “b” (÷0)
Constant:
   “K”: set of consumers
   “T”: set of times (evaluation unit)
   “E_{k,t}”: discharge capacity when consumer “k” discharges at the maximum output at time “t”
   “F_{k,t}”: charge capacity when consumer “k” charges at the maximum output at time “t”
   “G_{k,t}”: original scheduled charge and discharge capacities of consumer “k” at time “t” (+in the charging case, and—in the discharging case)
   “Aₖ”: available dischargeable capability of consumer “k” at DR start time
   “Cₖ”: available rechargeable capability of consumer “k” at DR start time
   “b (t)”: function of returning block including time “t”
   “Pb”: unit price of block b (bidding unit price)

Here, Expression (3) is an expression that represents revenue maximization. Expression (4) represents an expression of achieving the target value corresponding to the bidding capacity, by charging and discharging. Here, a method of ignoring the error between the reference value (e.g., the estimate immediately before DR start (one hour before or the like); see the reference value (one-minute value) in FIG. 8), and the original demand estimate (the demand estimate of the demand estimator 150; e.g., the estimate the day before) is adopted. However, the difference may be taken into account. Expression (5) is a restriction expression that represents that SoC of the storage battery of each consumer at each time is accommodated in a range from zero to the capacity.

Here, “E_{k,t}” denotes the discharge output of the storage battery of the consumer “k”. “F_{k,t}” is the charge output of the storage battery of the consumer “k”.

“Aₖ” denotes the amount corresponding to SoC of the consumer “k” at the DR start time point. “Cₖ” denotes an amount corresponding to a value obtained by subtracting SoC from the capacity of the consumer “k” at the DR start time point.

As a solution of obtaining the optimal solution or the suboptimal solution of the variables “X_{k,t}”, “Z_{k,t}”, and “I” described above, a mathematical programming solver, such as Gurobi Optimizer or CPLEX, may be used, or a metaheuristic, such as a gradient method, simulated annealing, or genetic algorithm, may be used.

Note that the formulation described above is an example. Any of other objective functions and restriction expressions may be used. For example, to add a condition for making the consumer “k” necessarily discharge depending on situations of the consumers, as additional problem setting, it is only required to add “X_{k,t}”=1 as a restriction expression. Likewise, to add a condition making the consumer “k” necessarily charge, it is only required to add “Z_{k,t}”=1 as a restriction expression. To add a condition never making the consumer “k” charge, it is only required to add “X_{k,t}”=0 as a restriction expression. Likewise, to add a condition never making the consumer “k” discharge, it is only required to add “Z_{k,t}”=0 as a restriction expression.

The formulation described above only optimizes actions in a case where the consumers operate as assumed.

If.
a case where the demand estimate of the consumer deviates from the reference value, or
a case where the consumers do not operate as requested is conceivable, the errors may be preliminarily estimated, and the optimization may be achieved using the estimates.

### Specific Example of Embodiment 3

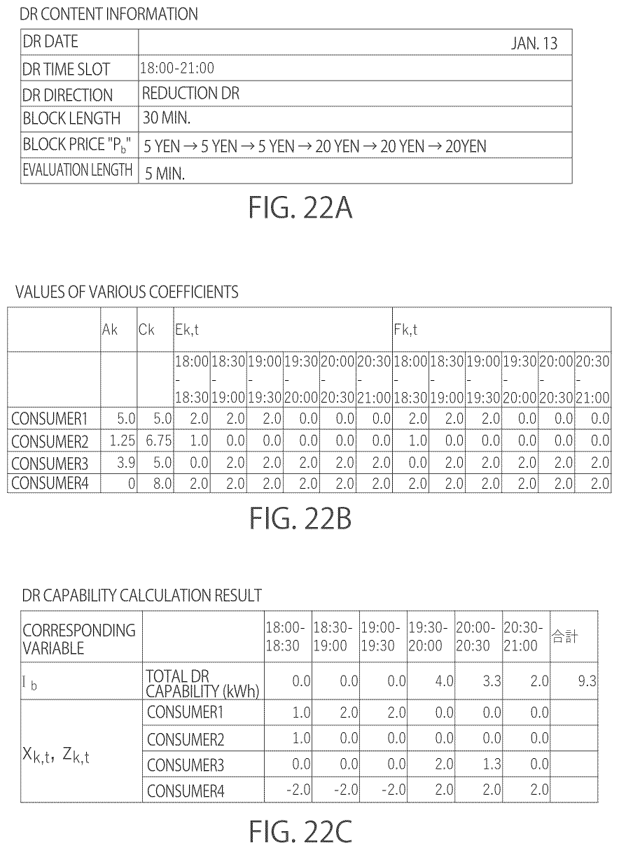

As a specific example of Embodiment 3, a case is discussed where 18:00-21:00 is divided into six blocks and bidding is performed, and the bidding unit prices of each block are 5 yen, 5 yen, 5 yen, 20 yen, 20 yen, and 20 yen, where the unit price for the latter half is expensive. The bidding unit prices are preliminarily determined by a freely selected method. The bidding unit prices of the blocks may be the same. FIG. 22A shows an example of the DR content information in this case. In a case where the SoC time-series estimates 141 and the disconnected time-series estimates 142 in FIG. 11, the storage battery specification information 180 in FIG. 15, and the DR content information 170 in FIG. 14 are received as inputs, each coefficient of the model described above is as shown in FIG. 22B. In this case, by solving the optimization problem, calculation results of the DR capability as in FIG. 22C are obtained. Here, the cell of “X_{k,t}”, “Z_{k,t}” of each consumer at each time indicates the value of “E_{k,t}”x“X_{k,t}” if “X_{k,t}” is not zero, and indicates the value of “−F_{k,t} x Z_{k,t}” if “Z_{k,t}” is not zero. Charging is negative, and discharging is positive (unit of kW).

The DR capability of each block in this case is 0.0 kWh, 0.0 kWh, 0.0 kWh, 4.0 kWh, 3.3 kWh, and 2.0 kWh. The DR capability of each block corresponds to the bidding capacity “I_{b}” of the corresponding block. The total of the DR capabilities is 9.3 kWh, which is the same as that in Embodiment 1. A plan where the bidding capacities are lean to later times with the higher unit price is obtained. For the consumer 4, a result where charging is on the former half and discharging is on the latter half is obtained. Thus, a plan of using up the charge and discharge available capabilities of all the consumers is obtained. Based on the calculation result in FIG. 22C, a bit with the bidding capacity “I_{b}” is made for each block, thus assuming profit optimization.

### Embodiment in Case where Reverse Power Flow is not Applicable or Charge and Discharge Capacities have Upper Limit: Embodiment 4

First, variables and constants are defined as follows.
“D_{k,t}”: demand estimate of consumer “k” at time “t”
“Uₖ”: power supply upper limit power (upper limit value of the meter value) of consumer “k”
“Iₖ”: power supply lower limit power (lower limit value of the meter value) of consumer “k”

In a case where no reverse power flow is achieved, control of the storage batteries so as to prevent the meter value from being less than “Iₖ” is sometimes performed. Alternatively, control of the storage batteries so as to prevent the meter value from being equal to “uₖ” or more is sometimes performed. Such conditions can be supported by changing “Eₖ” and “Fₖ” in the formulation described above as follows.

$${E}_{k , t} ← min ( {E}_{k , t} , max ( 0 , {D}_{k , t} - {I}_{k} ) ) \qquad ( 7 )$$

$${F}_{k , t} ← min ( {F}_{k , t} , max ( 0 , {u}_{k} - {D}_{k , t} ) ) \qquad ( 8 )$$

In calculation of the value, increase in prediction accuracy of demand estimation “D_{k,t}” can also increase the accuracy of DR capability.

### Specific Example of Embodiment 4

As a specific example of Embodiment 4, a case is discussed where a preliminary review of the balancing market is assumed, a bid in a single bidding block of 18:00-18:30 is made about the reduction DR in the DR time slot (in the balancing market, three hours constitute one block; here, for simplicity, 30 minutes are regarded as one block). Furthermore, a case where the evaluation time interval is five minutes is discussed. In other words, this is a case required to achieve a reduction object every five minutes.

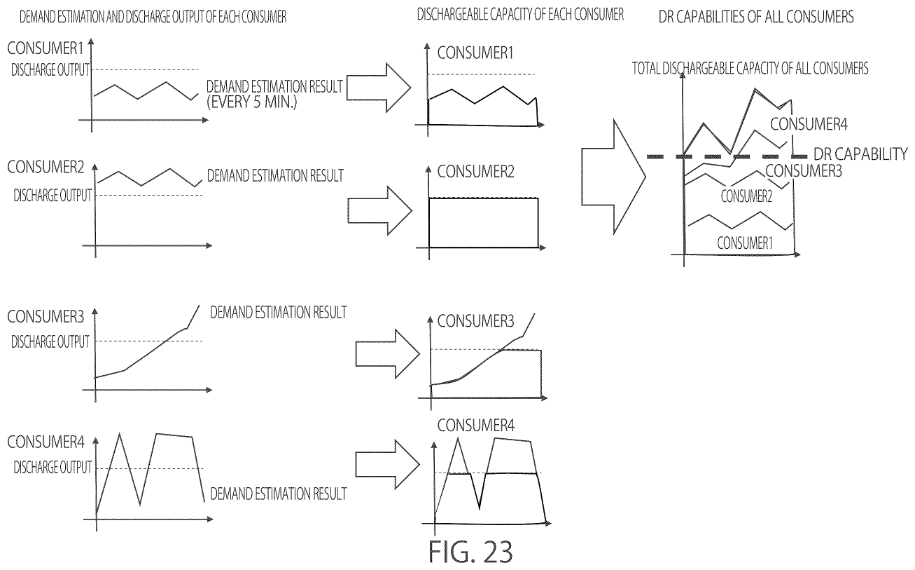

FIG. 23 shows a calculation example of DR capabilities in Embodiment 4.

Here, as shown in the left diagram of FIG. 23, a demand estimation result, and a discharge output (a value corresponding to “E_{k,t}” of Expression (7); for simplicity, it is assumed to be constant irrespective of time) of each consumer every five minutes are assumed to be obtained.

The center diagram of FIG. 23 shows the dischargeable capacities of the respective consumers in the case in the left diagram of FIG. 23, with hatched areas. In a case where the magnitude relationship between the discharge output and the demand estimation result is invariant as with the consumers 1 and 2, the dischargeable capacity is “ΣₜD_{k,t}” for the consumer 1, and “ΣₜE_{k,t}” for the consumer 2. The dischargeable capacity is not different from a case where a rough demand estimation result “(ΣₜD_{k,t})” every 30 minutes is obtained, and the dischargeable capacity is derived from “min (ΣₜD_{k,t}, ΣₜE_{k,t})”.

On the other hand, in a case where the demand estimation result monotonically increases (or monotonically decreases) in the block as with the consumer 3, and a case where the demand estimation result largely varies in the block as with the consumer 4, the magnitude relationship of “D_{k,t}” and “E_{k,t}” temporally varies. Consequently, through estimation of the dischargeable capacity with time intervals close to the evaluation intervals, a highly accurate dischargeable capacity can be obtained.

The right diagram of FIG. 23 schematically shows a method for obtaining the DR capability from the total of dischargeable capacities of all the consumers (a graph where the hatched portions in the center diagram of FIG. 23 are stacked). In the case of the balancing market, the target is required to be achieved over all the evaluation time slots. Accordingly, it is only required to adopt the minimum value of the stacked graph as the DR capability. In the example of the right diagram of FIG. 23, a value indicated by a horizontal broken line represents the DR capability.

The biases of demand of the consumers 3 and 4 are reflected in the minimum value of the stacked graph. Consequently, as a result of estimation of the demand of the consumers 3 and 4 every five minutes, the DR capability can be correctly estimated. Here, the description has been made without consideration of the capacities of the storage batteries. However, if the optimization in consideration of the capacities of the storage batteries is performed, the optimization in Embodiment 3 may be performed using “E_{k,t}” calculated in this embodiment.

### Embodiment of Optimizing Scenario in Consideration of Risk that Demand Estimation Result and the Like Deviate from Actual Demand Value (Estimation Deviation Risk): Embodiment 5

It is so far assumed that the demand estimation result and the SoC estimation result do not deviate from the actual values. However, the estimation result sometimes deviates in actuality. With this Embodiment 5, a flow of optimization in consideration of the estimation deviation risk as a method of conservatively estimating the DR capability is described.

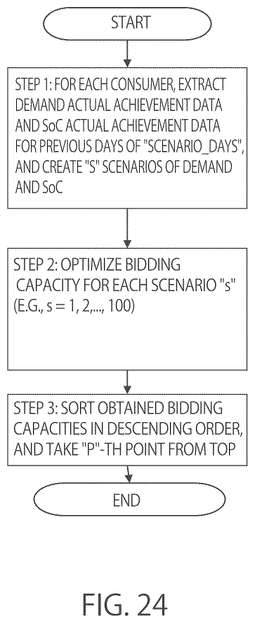

FIG. 24 shows an example of a flowchart in consideration of the estimation deviation risk.

In Step 1, demand actual achievement data, and SoC actual achievement data are extracted from previous data of the number of days indicated by “SCENARIO_DAYS” (parameter) on a customer-by-customer basis. “S” scenarios including the demand and SoC of the consumers are created. “S” may be one or more. The scenarios may be extracted data itself, or be generated by processing the extracted data.

For example, in a case of “SCENARIO_DAYS”=7, for a certain consumer, the demand and SoC actual achievement data items on dates varying depending on the scenario are extracted as predicted values in a form where three days before in the case of “s”=1, five days before in the case of “s”=2, two days before in the case of “s”=3, . . . . For each of the other consumers, data with the same scenario on a date different from that for the consumer is extracted. It is assumed that data items for at least two or more consumers with the same scenario are on different dates. Accordingly, a scenario where data items for the consumers on various dates are combined is obtained. For example, if there is a tendency that many customers have small SoC in the first block in the DR time slot, many scenarios where the total SoC in the first block is small can be obtained. However, according to some scenarios, several data items on consumers on a date with high SoC in the first block are extracted. Accordingly, a scenario with a slightly large total SoC in the first block can also be achieved. Note that it is assumed that the demand and SoC on the same date for each consumer are extracted. Thus, the consistency is held.

Next, in Step 2, for each scenario “s” (s=1, 2, . . . , S), the optimal bidding capacity of the corresponding scenario is obtained by any of the methods described in Embodiments 3 and 4.

In Step 3, the obtained results are sorted, for example, in a descending order of the total revenue (or total bidding capacity), and the “P”-th value from the bottom is adopted as the optimized result.

In this case, for example, with “P” having a smaller value, more conservative estimation can be performed. With “P” having a value of about “S/2”, average estimation can be performed. With “P” having a value close to “S”, estimation having a high risk (close to the maximum revenue) can be performed.

### Specific Example of Embodiment 5

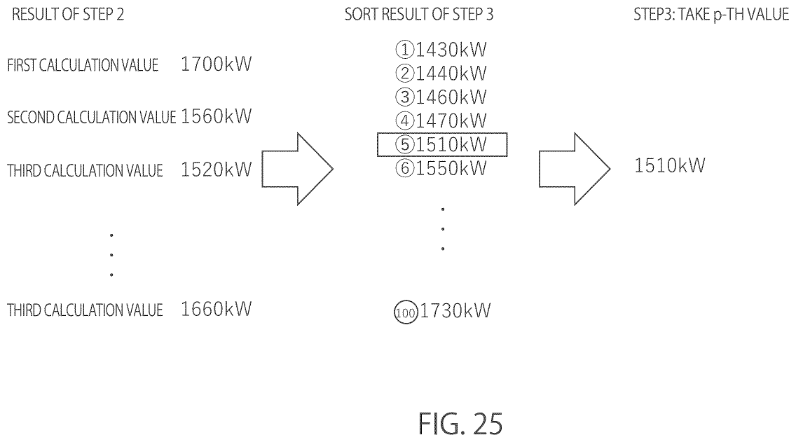

A specific example of Embodiment 5 is described with reference to FIG. 25. It is assumed that “S”=100 and “P”=5. For simplicity, a case of a single block is described.

FIG. 25 is a diagram showing a specific example of operation in Embodiment 5. The left diagram of FIG. 25 shows 1-st to 100-th optimized bidding capacities obtained as a result of Step 2. The center diagram of FIG. 25 shows the values of the 100 items arranged in a descending order. The right diagram of FIG. 25 shows (“P”=5)-th value taken from among them.

### Example of Output Screen

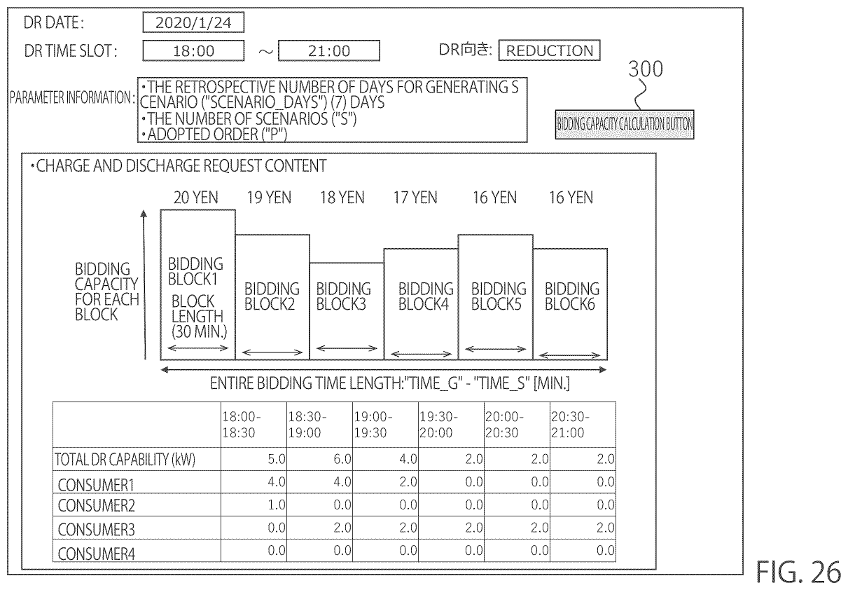

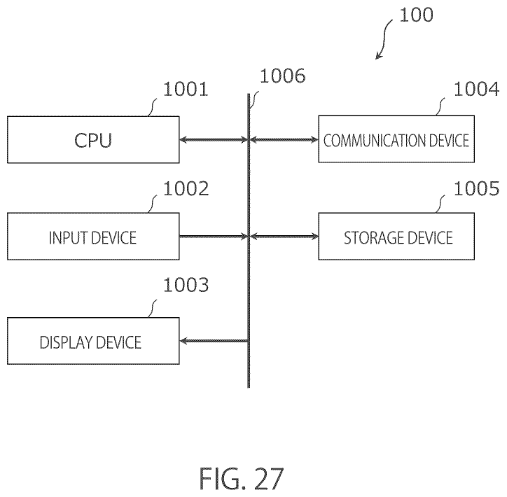

Lastly, an example of output screen is described. FIG. 26 shows an example of an output screen of the display 240. The output screen also includes a bidding capacity calculation button 300, as the operation input receiver 230. For example, on the output screen in FIG. 26, a DR date, a DR time slot, parameter information (“SCENARIO_DAYS”, “S”, “P”) and the like are input, and the bidding capacity calculation button 300 is pressed, thus outputting a calculation result on a screen portion for charge and discharge request content. According to the output form, the total DR capability may be shown in a table format, or a bar graph format. The DR capability of each consumer may be output as the breakdown of the total DR capability. It is assumed that the unit price for the bidding block every 30 minutes is predetermined by a freely selected method. The unit price varies depending on the bidding blocks in this example, but may have a common value among all the bidding blocks.

Furthermore, a process of transmitting data indicating the determined bidding capacities for the respective blocks, to an electricity exchange market system that performs the electricity exchange market may also be performed.

In the case of economic DR, the summation of the procurement capacities from the consumers is adopted. Accordingly, the procurement capacity from the electricity exchange market that is what is obtained by subtracting the procurement capacity of each consumer from the difference between the planned value and the achievement expectation value (estimated power demand value) on a block-by-block basis may be output on the screen as the bidding capacity of power for bidding for the electricity exchange market. Furthermore, a process of transmitting data indicating the procurement from the electricity exchange market as the bidding capacity, to an electricity exchange market system that performs the electricity exchange market may also be performed.

### (Hardware Configuration)

A hardware configuration of the DR capability estimation apparatus according to the above embodiments will be described with reference to FIG. 27.

FIG. 27 shows a hardware configuration of the DR capability estimation apparatus, which is an information processing apparatus according to the embodiments. As shown in FIG. 27, the DR capability estimation apparatus according to the embodiments of the present invention is made up of a computer 1000. The computer 1000 includes a CPU 1001 (central processing unit), input devices 1002, a display device 1003, a communications device 1004, and a storage device 1005, which are interconnected via a bus 1006.

The CPU 1001 is a control unit and arithmetic unit of the computer 1000. The CPU 1001 performs computational processes based on data and programs received as input from various devices (e.g., the input devices 1002, the communications device 1004, and the storage device 1005) connected via the bus 1006 and outputs computational results and control signals to various devices (e.g., the display device 1003, the communications device 1004, and the storage device 1005) connected via the bus 1006.

Specifically, the CPU 1001 executes an OS (operating system) of the computer 1000, a DR capability estimation program (information processing program), and the like and controls various devices making up the computer 1000. The DR capability estimation program makes the computer 1000 implement the above-mentioned functional components of the DR capability estimation apparatus. As the CPU 1001 executes the DR capability estimation program, the computer 1000 functions as the DR capability estimation apparatus. The input devices 1002 are used to enter information to the computer 1000. The input devices 1002 are, for example, a keyboard, a mouse, and/or a touch panel, but are not limited thereto. The input devices 1002 allow the user to enter input information.

The display device 1003 is used to display images and videos. The display device 1003 is, for example, an LCD (liquid crystal display), a CRT (cathode ray tube), or a PDP (plasma display panel), but is not limited thereto. The user can display optimization results on the display device 1003.

The communications device 1004 allows the computer 1000 to communicate with an external device by radio or by wire. The communications device 1004 includes a modem, a hub, and a router, but is not limited thereto. The input information may be sent from the external device via the communications device 1004.

The storage device 1005 is a storage medium configured to store the OS of the computer 1000, the DR capability estimation program, data necessary for execution of the DR capability estimation program, and data generated by the execution of the DR capability estimation program. The storage device 1005 includes a main storage device and external storage devices. The main storage device is, for example, RAM, DRAM, or SRAM, but is not limited thereto. The external storage devices are a hard disk, an optical disk, a flash memory, and a magnetic tape, but are not limited thereto. Note that the computer 1000 may include one or more of the CPU 1001, the input devices 1002, the display device 1003, the communications device 1004, and the storage device 1005, and may be connected with a peripheral such as a printer or a scanner. The DR capability estimation apparatus may be made up of the single computer 1000 or may be configured as a system made up of a plurality of the computers 1000 connected with one another. Furthermore, the DR capability estimation program may be prestored in the storage device 1005 of the computer 1000, stored in a storage medium such as a CD-ROM, or uploaded to the Internet. In any case, when executed by being installed on the computer 1000, the DR capability estimation program can make up the DR capability estimation apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

The embodiments as described before may be configured as below.

### CLAUSES

Clause 1. An information processing apparatus, comprising a processing circuitry configured to estimate, based on histories of charge and discharge of storage batteries of one or more consumers in a first period, remaining capacities of the storage batteries in a second period different from the first period, and calculate a power adjustable capacity that is a total of rechargeable capacities or dischargeable capacities of the storage batteries of the one or more consumers in the second period, based on estimates of the remaining capacities of the storage batteries.

Clause 2. The information processing apparatus according to clause 1,
wherein the processing circuitry estimates connected/disconnected time periods that are time periods during which the storage batteries are connected in a rechargeable and dischargeable manner or disconnected at the consumers, in the second period, based on a history of the connected/disconnected time periods of the storage batteries, and
calculates rechargeable capacities or dischargeable capacities of the storage batteries of the consumers, based on estimates of the connected/disconnected time periods.

Clause 3. The information processing apparatus according to clause 1 or 2,
wherein the processing circuitry obtains information on power demand of the one or more consumers in the second period, and
calculates the rechargeable capacities or the dischargeable capacities of the storage batteries of the consumers, based further on the information on power demand.

Clause 4. The information processing apparatus according to clause 3,
wherein the processing circuitry estimates the power demand of the consumers in the second period, based on histories of meter values at the consumers in a third period, and
calculates the rechargeable capacities or the dischargeable capacities of the storage batteries of the consumers, based further on the estimated power demand.

Clause 5. The information processing apparatus according to clause 4,
wherein the processing circuitry estimates charge output values and discharge output values of the storage batteries in the second period on a time-by-time basis, based on the power demand, and based on the histories of charge and discharge of the storage batteries, and,
calculates the rechargeable capacities or the dischargeable capacities of the storage batteries of the consumers, based further on the charge output values and the discharge output values estimated, and the power demand estimated.

6. The information processing apparatus according to clause 5, wherein the processing circuitry calculates the rechargeable capacities or the dischargeable capacities of the storage batteries of the consumers, based further on control preset for charge and discharge operations of the storage batteries.

Clause 7. The information processing apparatus according to any one of clauses 1 to 6
wherein the processing circuitry generates a plurality of scenarios each including estimates of remaining capacities of the storage batteries of the plurality of consumers in the second period,
estimates the power adjustable capacities individually for the respective scenarios, and
selects the power adjustable capacity from among the power adjustable capacities estimated individually for the respective scenarios.

Clause 8. The information processing apparatus according to clause 2,
wherein the processing circuitry generates a plurality of scenarios each including
   estimates of remaining capacities of the storage batteries of the plurality of consumers in the second period, and
   estimates of the connected/disconnected time period, based on the histories of charge and discharge of the storage batteries and on histories of the connected/disconnected time period, and
estimates the power adjustable capacities individually for the respective scenarios, and
selects the power adjustable capacity from among the power adjustable capacities for the respective scenarios.

Clause 9. The information processing apparatus according to any one of clauses 1 to 8, wherein the processing circuitry determines a bidding capacity in the second period for a balancing market, based on the power adjustable capacity.

Clause 10. The information processing apparatus according to clause 9,
wherein the processing circuitry transmits data indicating the determined bidding capacity, to a balancing market system which performs processing of the balancing market.

Clause 11. The information processing apparatus according to any one of clauses 4 to 6,
wherein the processing circuitry receives, as inputs, a number of blocks that divide the second period and prices for the respective blocks,
estimates the power adjustable capacities individually for the respective blocks obtained by dividing the second period by the number of blocks,
determines the power adjustable capacities for the respective blocks as a restriction condition,
calculates procurement capacities of power from the consumers for the individual blocks so as to maximize or quasi-maximize a summation of individual products of unit prices for the respective blocks and procurement capacities for the respective blocks, and
determines electric energy obtained by subtracting the procurement capacities for the respective blocks from differences between
   planned values of power demand for the respective blocks and
   estimates of the power demand for the respective blocks,
the determined electric energy being the bidding capacities for the respective blocks to an electricity exchange market.

Clause 12. The information processing apparatus according to clause 11,
wherein the processing circuitry transmits data indicating the determined bidding capacities for the respective blocks, to an electricity exchange market system that performs processing of the electricity exchange market.

Clause 13. The information processing apparatus according to any one of clauses 1 to 12,
wherein the second period is a target time slot of demand response.

Clause 14. The information processing apparatus according to clause 13,
wherein the processing circuitry receives command information on the demand response designating the second period, and controls charge and discharge of the storage batteries of the one or more consumers in the second period, based on the command information.

Clause 15. An information processing method, comprising
estimating, based on histories of charge and discharge of storage batteries of one or more consumers in a first period, remaining capacities of the storage batteries in a second period different from the first period; and
calculating a power adjustable capacity that is a total of rechargeable capacities or dischargeable capacities of the storage batteries of the one or more consumers in the second period, based on estimates of the remaining capacities of the storage batteries.

Clause 16. A non-transitory computer readable medium having a computer program stored therein which causes a computer to perform processes, comprising:
estimating, based on histories of charge and discharge of storage batteries of one or more consumers in a first period, remaining capacities of the storage batteries in a second period different from the first period; and
calculating a power adjustable capacity that is a total of rechargeable capacities or dischargeable capacities of the storage batteries of the one or more consumers in the second period, based on estimates of the remaining capacities of the storage batteries.

Clause 17. An information processing system, comprising
a plurality of batteries of one or more consumers; and
a processing circuitry configured to estimate, based on histories of charge and discharge of the storage batteries of the one or more consumers in a first period, remaining capacities of the storage batteries in a second period different from the first period, and
calculate a power adjustable capacity that is a total of rechargeable capacities or dischargeable capacities of the storage batteries of the one or more consumers in the second period, based on estimates of the remaining capacities of the storage batteries.

1. An information processing apparatus, comprising
a processing circuitry configured to estimate, based on histories of charge and discharge of storage batteries of one or more consumers in a first period, remaining capacities of the storage batteries in a second period different from the first period, and
calculate a power adjustable capacity that is a total of rechargeable capacities or dischargeable capacities of the storage batteries of the one or more consumers in the second period, based on estimates of the remaining capacities of the storage batteries.

2. The information processing apparatus according to claim 1,
wherein the processing circuitry estimates connected/disconnected time periods that are time periods during which the storage batteries are connected in a rechargeable and dischargeable manner or disconnected at the consumers, in the second period, based on a history of the connected/disconnected time periods of the storage batteries, and
calculates rechargeable capacities or dischargeable capacities of the storage batteries of the consumers, based on estimates of the connected/disconnected time periods.

3. The information processing apparatus according to claim 1,
wherein the processing circuitry obtains information on power demand of the one or more consumers in the second period, and
calculates the rechargeable capacities or the dischargeable capacities of the storage batteries of the consumers, based further on the information on power demand.

4. The information processing apparatus according to claim 3,
wherein the processing circuitry estimates the power demand of the consumers in the second period, based on histories of meter values at the consumers in a third period, and
calculates the rechargeable capacities or the dischargeable capacities of the storage batteries of the consumers, based further on the estimated power demand.

5. The information processing apparatus according to claim 4,
wherein the processing circuitry estimates charge output values and discharge output values of the storage batteries in the second period on a time-by-time basis, based on the power demand, and based on the histories of charge and discharge of the storage batteries, and,
calculates the rechargeable capacities or the dischargeable capacities of the storage batteries of the consumers, based further on the charge output values and the discharge output values estimated, and the power demand estimated.

6. The information processing apparatus according to claim 5,
wherein the processing circuitry calculates the rechargeable capacities or the dischargeable capacities of the storage batteries of the consumers, based further on control preset for charge and discharge operations of the storage batteries.

7. The information processing apparatus according to claim 1,
wherein the processing circuitry generates a plurality of scenarios each including estimates of remaining capacities of the storage batteries of the plurality of consumers in the second period,
estimates the power adjustable capacities individually for the respective scenarios, and
selects the power adjustable capacity from among the power adjustable capacities estimated individually for the respective scenarios.

8. The information processing apparatus according to claim 2,
wherein the processing circuitry generates a plurality of scenarios each including
estimates of remaining capacities of the storage batteries of the plurality of consumers in the second period, and
estimates of the connected/disconnected time period, based on the histories of charge and discharge of the storage batteries and on histories of the connected/disconnected time period, and
estimates the power adjustable capacities individually for the respective scenarios, and
selects the power adjustable capacity from among the power adjustable capacities for the respective scenarios.

9. The information processing apparatus according to claim 1,
wherein the processing circuitry determines a bidding capacity in the second period for a balancing market, based on the power adjustable capacity.

10. The information processing apparatus according to claim 9,
wherein the processing circuitry transmits data indicating the determined bidding capacity, to a balancing market system which performs processing of the balancing market.

11. The information processing apparatus according to claim 4,
wherein the processing circuitry receives, as inputs, a number of blocks that divide the second period and prices for the respective blocks,
estimates the power adjustable capacities individually for the respective blocks obtained by dividing the second period by the number of blocks,
determines the power adjustable capacities for the respective blocks as a restriction condition,
calculates procurement capacities of power from the consumers for the individual blocks so as to maximize or quasi-maximize a summation of individual products of unit prices for the respective blocks and procurement capacities for the respective blocks, and
determines electric energy obtained by subtracting the procurement capacities for the respective blocks from differences between
planned values of power demand for the respective blocks and
estimates of the power demand for the respective blocks,
the determined electric energy being the bidding capacities for the respective blocks to an electricity exchange market.

12. The information processing apparatus according to claim 11,
wherein the processing circuitry transmits data indicating the determined bidding capacities for the respective blocks, to an electricity exchange market system that performs processing of the electricity exchange market.

13. The information processing apparatus according to claim 1,
wherein the second period is a target time slot of demand response.

14. The information processing apparatus according to claim 13,
wherein the processing circuitry receives command information on the demand response designating the second period, and controls charge and discharge of the storage batteries of the one or more consumers in the second period, based on the command information.

15. An information processing method, comprising
estimating, based on histories of charge and discharge of storage batteries of one or more consumers in a first period, remaining capacities of the storage batteries in a second period different from the first period; and
calculating a power adjustable capacity that is a total of rechargeable capacities or dischargeable capacities of the storage batteries of the one or more consumers in the second period, based on estimates of the remaining capacities of the storage batteries.

16. A non-transitory computer readable medium having a computer program stored therein which causes a computer to perform processes, comprising:
estimating, based on histories of charge and discharge of storage batteries of one or more consumers in a first period, remaining capacities of the storage batteries in a second period different from the first period; and
calculating a power adjustable capacity that is a total of rechargeable capacities or dischargeable capacities of the storage batteries of the one or more consumers in the second period, based on estimates of the remaining capacities of the storage batteries.

17. An information processing system, comprising
a plurality of batteries of one or more consumers; and
a processing circuitry configured to estimate, based on histories of charge and discharge of the storage batteries of the one or more consumers in a first period, remaining capacities of the storage batteries in a second period different from the first period, and
calculate a power adjustable capacity that is a total of rechargeable capacities or dischargeable capacities of the storage batteries of the one or more consumers in the second period, based on estimates of the remaining capacities of the storage batteries.
